(19) United States
(12) Patent Application Publication
(10) Pub. No.: US 2011/0262865 A1
(43) Pub. Date: Oct. 27, 2011

(54) RADIATION-SENSITIVE RESIN COMPOSITION AND POLYMER

(75) Inventors: Yukio NISHIMURA, Tokyo (JP); Yasuhiko MATSUDA, Tokyo (JP); Kaori SAKAI, Tokyo (JP); Makoto SUGIURA, Tokyo (JP)

(73) Assignee: JSR Corporation, Tokyo (JP)

(21) Appl. No.: 13/115,990

(22) Filed: May 26, 2011

Related U.S. Application Data
(63) Continuation of application No. PCT/JP2009/069925, filed on Nov. 26, 2009.

(30) Foreign Application Priority Data
Nov. 26, 2008 (JP) 2008-300971
Nov. 28, 2008 (JP) 2008-305555
Nov. 28, 2008 (JP) 2008-305613
Nov. 28, 2008 (JP) 2008-305615
Nov. 28, 2008 (JP) 2008-305622
Dec. 8, 2008 (JP) 2008-312581

(51) Int. Cl. G03F 7/004; C08F 220/24; C08F 220/38; C08F 22/20

(52) U.S. Cl. 430/285.1; 526/270; 526/245

(57) ABSTRACT

A radiation-sensitive resin composition includes a resin and a photoacid generator. The resin includes a polymer including a first repeating unit shown by a following formula (1) and an acid-dissociable group-containing repeating unit,

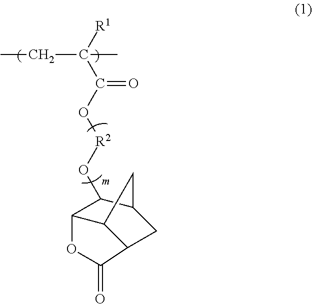

wherein R¹ represents a hydrogen atom or a methyl group, R² represents an alkylene group having 1 to 12 carbon atoms or an alicyclic alkylene group, and m is an integer from 1 to 3.

### CROSS-REFERENCE TO RELATED APPLICATIONS

The present application is a continuation application of International Application No. PCT/JP2009/069925, filed Nov. 26, 2009, which claims priority to Japanese Patent Application No. 2008-312581, filed Dec. 8, 2008, Japanese Patent Application No. 2008-305622, filed Nov. 28, 2008, Japanese Patent Application No. 2008-305615, filed Nov. 28, 2008, Japanese Patent Application No. 2008-305613, filed Nov. 28, 2008, Japanese Patent Application No. 2008-305555, filed Nov. 28, 2008, and Japanese Patent Application No. 2008-300971, filed Nov. 26, 2008. The contents of these applications are incorporated herein by reference in their entirety.

### BACKGROUND OF THE INVENTION

1. Field of the Invention

The present invention relates to a radiation-sensitive resin composition and a polymer.

2. Discussion of the Background

When applying deep ultraviolet rays (e.g., KrF excimer laser light or ArF excimer laser light) or the like to a chemically-amplified radiation-sensitive resin composition, an acid is generated in the exposed area, and a difference in solubility rate in a developer occurs between the exposed area and the unexposed area due to the acid. A resist pattern is formed on a substrate by utilizing the difference in solubility rate.

When using a KrF excimer laser as the light source, an excellent pattern can be formed with high sensitivity and high resolution by utilizing a chemically-amplified radiation-sensitive resin composition that mainly includes a resin having a polyhydroxystyrene basic skeleton that has small absorption at 248 nm.

For example, an ArF excimer laser (wavelength: 193 nm) has been used as a light source having a shorter wavelength aimed at implementing more advanced microfabrication. It may be difficult to use a monomer including an aromatic group (e.g., polyhydroxystyrene) when using an ArF excimer laser as a light source due to large absorption at 193 nm (i.e., the wavelength of an ArF excimer laser). Therefore, a radiation-sensitive resin composition that includes a resin having an alicyclic hydrocarbon skeleton that does not have large absorption at 193 nm has been used as a lithographic material when using an ArF excimer laser.

A composition that includes a resin having an alicyclic hydrocarbon skeleton and including a repeating unit having a lactone skeleton exhibits significantly improved resolution (see Japanese Patent Application Publication (KOKAI) No. 9-73173, U.S. Pat. No. 6,388,101, Japanese Patent Application Publication (KOKAI) No. 2000-159758, Japanese Patent Application Publication (KOKAI) No. 2001-109154, Japanese Patent Application Publication (KOKAI) No. 2004-101642, Japanese Patent Application Publication (KOKAI) No. 2003-113174, Japanese Patent Application Publication (KOKAI) No. 2003-147023, Japanese Patent Application Publication (KOKAI) No. 2002-308866, Japanese Patent Application Publication (KOKAI) No. 2002-371114, Japanese Patent Application Publication (KOKAI) No. 2003-64134, Japanese Patent Application Publication (KOKAI) No. 2003-270787, Japanese Patent Application Publication (KOKAI) No. 2000-26446, Japanese Patent Application Publication (KOKAI) No. 2000-122294, and Japanese Patent No. 3952946, for example).

For example, Japanese Patent Application Publication (KOKAI) No. 9-73173 and U.S. Pat. No. 6,388,101 disclose a radiation-sensitive resin composition that includes a resin including a repeating unit having a mevalonic lactone skeleton or a γ-butyrolactone skeleton. Japanese Patent Application Publication (KOKAI) No. 2000-159758, Japanese Patent Application Publication (KOKAI) No. 2001-109154, Japanese Patent Application Publication (KOKAI) No. 2004-101642, Japanese Patent Application Publication (KOKAI) No. 2003-113174, Japanese Patent Application Publication (KOKAI) No. 2003-147023, Japanese Patent Application Publication (KOKAI) No. 2002-308866, Japanese Patent Application Publication (KOKAI) No. 2002-371114, Japanese Patent Application Publication (KOKAI) No. 2003-64134, Japanese Patent Application Publication (KOKAI) No. 2003-270787, Japanese Patent Application Publication (KOKAI) No. 2000-26446, Japanese Patent Application Publication (KOKAI) No. 2000-122294, and Japanese Patent No. 3952946 disclose a radiation-sensitive resin composition that includes a resin including a repeating unit having an alicyclic lactone skeleton.

### SUMMARY OF THE INVENTION

According to one aspect of the present invention, a radiation-sensitive resin composition includes a resin and a photoacid generator. The resin includes a polymer including a first repeating unit shown by a following formula (1) and an acid-dissociable group-containing repeating unit,

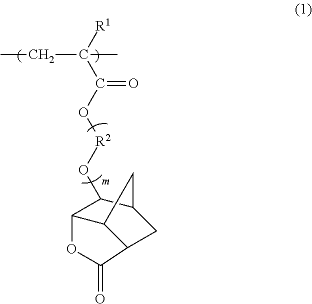

wherein R¹ represents a hydrogen atom or a methyl group, R² represents an alkylene group having 1 to 12 carbon atoms or an alicyclic alkylene group, and m is an integer from 1 to 3.

According to another aspect of the present invention, a polymer has a weight average molecular weight of 1000 to 100,000. The polymer includes a first repeating unit shown by a following formula (1) and an acid-dissociable group-containing repeating unit,

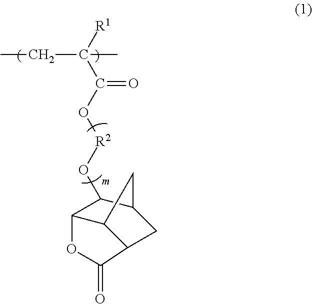

wherein R¹ represents a hydrogen atom or a methyl group, R² represents an alkylene group having 1 to 12 carbon atoms or an alicyclic alkylene group, and m is an integer from 1 to 3.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a view showing a typical watermark defect; and

FIG. 2 is a view showing a typical bubble defect.

### DESCRIPTION OF THE EMBODIMENTS

The embodiments of the invention are described below with reference to the accompanying drawings, wherein like reference numerals designate corresponding or identical elements throughout the various drawings. Note that the invention is not limited to the following exemplary embodiments. Various modifications and variations may be made of the following exemplary embodiments without departing from the scope of the invention based on the knowledge of a person having ordinary skill in the art.

A radiation-sensitive resin composition according to one embodiment of the invention includes (A) a resin that includes a repeating unit (A1) shown by the formula (1), and an acid-dissociable group-containing repeating unit, and (B) a photoacid generator. The radiation-sensitive resin composition may further include a nitrogen-containing compound (hereinafter may be referred to as “nitrogen-containing compound (C)”), an additive (hereinafter may be referred to as “additive (D)”), a solvent (hereinafter may be referred to as “solvent (E)”), and the like. Each component is described below.

### Resin (A)

The resin (A) includes the repeating unit (A1) shown by the formula (1), and an acid-dissociable group-containing repeating unit.

The alkylene group having 1 to 12 carbon atoms represented by R² in the formula (1) is preferably a linear or branched alkylene group. Examples of the alkylene group having 1 to 12 carbon atoms represented by R² in the formula (1) include a methylene group, an ethylene group, a propylene group, an isopropylene group, an n-butylene group, an isobutylene group, and the like.

The alicyclic alkylene group represented by R² in the formula (1) may be a monocyclic or bridged cyclic alkylene group. Examples of the alicyclic alkylene group represented by R² in the formula (1) include a 1,4-cyclohexylene group, a 1,3-cyclohexylene group, a 1,2-cyclohexylene group, a 2,3-bicyclo[2.2.1]heptylene group, a 2,5-bicyclo[2.2.1]heptylene group, a 2,6-bicyclo[2.2.1]heptylene group, a 1,3-adamantylene group, and the like.

Among these, a methylene group, an ethylene group, a propylene group, and an isopropylene group are preferable.

Each repeating unit is obtained by polymerizing a monomer that includes a polymerizable unsaturated bond. Examples of a preferable monomer that produces the repeating unit (A1) include monomers shown by the following formulas (1-1) to (1-5). Note that R¹ in the formulas (1-1) to (1-5) represents a hydrogen atom or a methyl group.

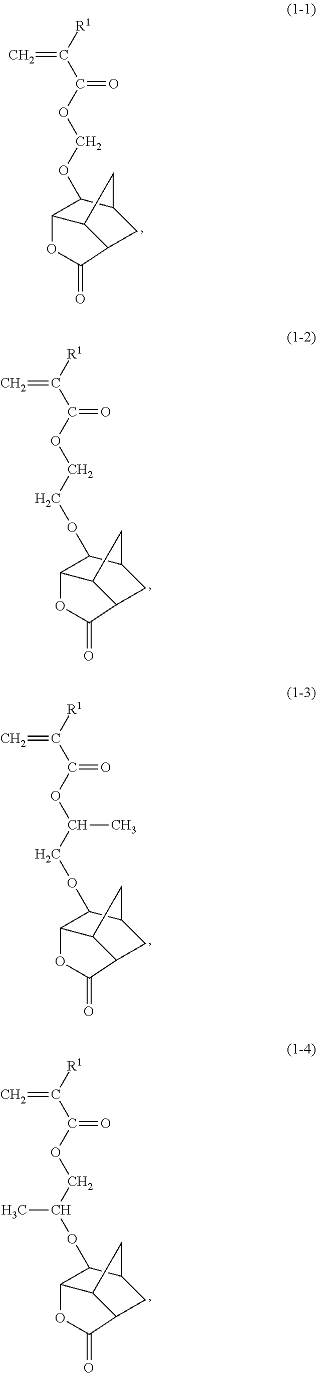

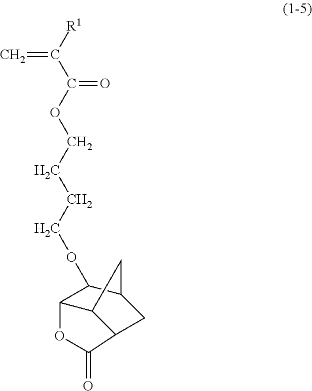

The monomers shown by the formulas (1-1) to (1-5) may be used either individually or in combination.

The acid-dissociable group-containing repeating unit included in the resin (A) is preferably at least one repeating unit selected from a repeating unit (A2) and a repeating unit (A3). The repeating unit (A2) is preferable from the viewpoint of LWR.

The repeating unit (A2) is shown by the formula (2).

The alkyl group having 1 to 4 carbon atoms represented by R³ in the formula (2) is preferably a linear or branched alkyl group. Examples of the alkyl group having 1 to 4 carbon atoms represented by R³ in the formula (2) include a methyl group, an ethyl group, a propyl group, an isopropyl group, an isobutyl group, a t-butyl group, and the like.

Examples of a preferable monomer that produces the repeating unit (A2) (n is preferably an integer from 1 to 5) include 1-methyl-1-cyclopentyl (meth)acrylate, 1-ethyl-1-cyclopentyl (meth)acrylate, 1-isopropyl-1-cyclopentyl (meth)acrylate, 1-methyl-1-cyclohexyl (meth)acrylate, 1-ethyl-1-cyclohexyl (meth)acrylate, 1-isopropyl-1-cyclohexyl (meth)acrylate, 1-methyl-1-cycloheptyl (meth)acrylate, 1-ethyl-1-cycloheptyl (meth)acrylate, 1-isopropyl-1-cycloheptyl (meth)acrylate, 1-methyl-1-cyclooctyl (meth)acrylate, 1-ethyl-1-cyclooctyl (meth)acrylate, 1-isopropyl-1-cyclooctyl (meth)acrylate, and the like.

These monomers may be used either individually or in combination.

The repeating unit (A3) is shown by at least one formula selected from the following formulas (3-1) and (3-2).

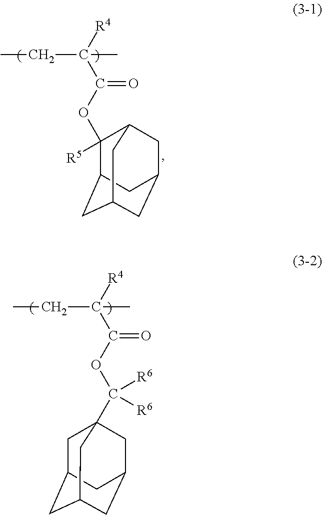

wherein R⁴ represents a hydrogen atom, a methyl group, or a trifluoromethyl group.

R⁵ in the formula (3-1) represents an alkyl group having 1 to 4 carbon atoms. The alkyl group having 1 to 4 carbon atoms represented by R⁵ in the formula (3-1) is preferably a linear or branched alkyl group. Examples of the alkyl group having 1 to 4 carbon atoms represented by R⁵ in the formula (3-1) include a methyl group, an ethyl group, a propyl group, an isopropyl group, an isobutyl group, a t-butyl group, and the like.

R⁶ in the formula (3-2) individually represent an alkyl group having 1 to 4 carbon atoms. The alkyl group having 1 to 4 carbon atoms represented by R⁶ in the formula (3-2) is preferably a linear or branched alkyl group. Examples of the alkyl group having 1 to 4 carbon atoms represented by R⁶ in the formula (3-2) include a methyl group, an ethyl group, a propyl group, an isopropyl group, an isobutyl group, a t-butyl group, and the like.

Examples of a preferable monomer that produces the repeating unit (3) include 2-methyladamant-2-yl (meth)acrylate, 2-ethyladamant-2-yl (meth)acrylate, 2-n-propyladamant-2-yl (meth)acrylate, 2-isopropyladamant-2-yl (meth)acrylate, 1-(adamant-1-yl)-1-methylethyl (meth)acrylate, 1-(adamant-1-yl)-1-ethylethyl (meth)acrylate, 1-(adamant-1-yl)-1-methylpropyl (meth)acrylate, 1-(adamant-1-yl)-1-ethylpropyl (meth)acrylate, and the like.

These monomers may be used either individually or in combination.

The resin (A) may further include a repeating unit (A4). The repeating unit (A4) is shown by the following formula (4).

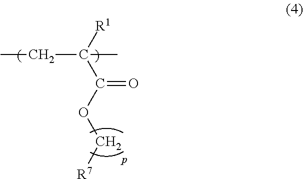

wherein R¹ represents a hydrogen atom or a methyl group.

R⁷ in the formula (4) represents a hydrogen atom, a hydroxyl group, or an acyl group. Examples of the acyl group represented by R⁷ include a formyl group, an acetyl group, a propionyl group, a butyryl group, an isobutyryl group, a valeryl group, an isovaleryl group, a pivaloyl group, a hexanoyl group, and the like.

p in the formula (4) is an integer from 1 to 18, preferably an integer from 1 to 10, and more preferably an integer from 1 to 5.

Examples of a monomer that produces the repeating unit (A4) include monomers shown by the following formulas (4-1) and (4-2). Note that R¹ in the formulas (4-1) and (4-2) represents a hydrogen atom or a methyl group.

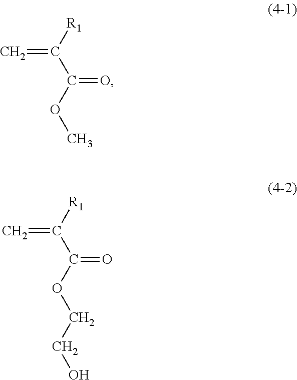

Examples of a preferable monomer that produces the repeating unit (A4) include methyl (meth)acrylate, ethyl (meth)acrylate, propyl (meth)acrylate, n-butyl (meth)acrylate, i-butyl (meth)acrylate, 2-hydroxyethyl (meth)acrylate, 3-hydroxypropyl (meth)acrylate, and the like.

The resin (A) may further include a repeating unit (A5). The repeating unit (A5) is shown by the following formula (5-1) or (5-2).

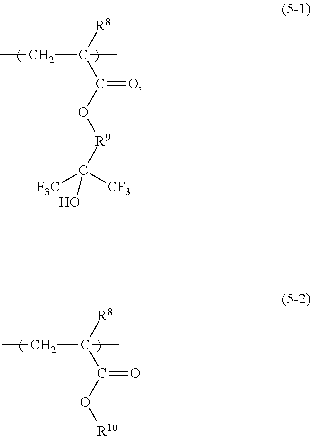

wherein R⁸ represents a hydrogen atom, an alkyl group having 1 to 4 carbon atoms, a trifluoromethyl group, or a hydroxymethyl group.

R⁹ in the formula (5-1) represents a divalent chain-like or cyclic hydrocarbon group. Examples of the divalent chain-like or cyclic hydrocarbon group may be an alkylene glycol group or an alkylene ester group, for example. Preferable examples of the divalent chain-like or cyclic hydrocarbon group represented by R⁹ include unsaturated chain-like hydrocarbon groups such as a methylene group, an ethylene group, a propylene group (e.g., 1,3-propylene group and 1,2-propylene group), a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, an icosylene group, a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; monocyclic hydrocarbon groups such as cycloalkylene groups having 3 to 10 carbon atoms such as a cyclobutylene group (e.g., 1,3-cyclobutylene group), a cyclopentylene group (e.g., 1,3-cyclopentylene group), a cyclohexylene group (e.g., 1,4-cyclohexylene group), and a cyclooctylene group (e.g., 1,5-cyclooctylene group); bridged cyclic hydrocarbon groups such as dicyclic, tricyclic, or tetracyclic hydrocarbon groups having 4 to 30 carbon atoms such as a norbornylene group (e.g., 1,4-norbornylene group and 2,5-norbornylene group), and an admantylene group (e.g., 1,5-admantylene group and 2,6-admantylene group); and the like.

Examples of a preferable monomer that produces the repeating unit shown by the formula (5-1) include (1,1,1-trifluoro-2-trifluoromethyl-2-hydroxy-3-propyl) (meth)acrylate, (1,1,1-trifluoro-2-trifluoromethyl-2-hydroxy-4-butyl)(meth)acrylate, (1,1,1-trifluoro-2-trifluoromethyl-2-hydroxy-5-pentyl)(meth)acrylate, (1,1,1-trifluoro-2-trifluoromethyl-2-hydroxy-4-pentyl)(meth)acrylate, 2-[[5-(1′,1′,1′-trifluoro-2′-trifluoromethyl-2′-hydroxy)propyl]bicyclo[2.2.1]heptyl](meth)acrylate, 3-[[8-(1′,1′,1′-trifluoro-2′-trifluoromethyl-2′-hydroxy)propyl]tetracyclo[6.2.1.1^{3,6}.0^{2,7}]-dodec yl](meth)acrylate, 4-[[9-(1′,1′,1′-trifluoro-2′-trifluoromethyl-2′-hydroxy)propyl]tetracyclo[6.2.1.1^{3,6}.0^{2,7}]-dodec yl](meth)acrylate, and the like.

Examples of R¹⁰ in the formula (5-2) include a trifluoromethyl group, a 2,2,2-trifluoroethyl group, a perfluoroethyl group, a perfluoro-n-propyl group, a perfluoro-i-propyl group, a perfluoro-n-butyl group, a perfluoro-1-butyl group, a perfluoro-t-butyl group, a perfluorocyclohexyl group, a 2-(1,1,1,3,3,3-hexafluoro)propyl group, a 2,2,3,3,4,4,5,5-octafluoropentyl group, a 2,2,3,3,4,4,5,5-octafluorohexyl group, a perfluorocyclohexylmethyl group, a 2,2,3,3,3-pentafluoropropyl group, a 2,2,3,3,4,4,4-heptafluoropentyl group, a 3,3,4,4,5,5,6,6,7,7,8,8,9,9,10,10,10-heptadecafluorodecyl group, a 5-trifluoromethyl-3,3,4,4,5,6,6,6-octafluorohexyl group, and the like.

Examples of a preferable monomer that produces the repeating unit shown by the formula (5-2) include trifluoromethyl (meth)acrylate, 2,2,2-trifluoroethyl (meth)acrylate, perfluoro-ethyl (meth)acrylate, perfluoro-n-propyl (meth)acrylate, perfluoro-i-propyl (meth)acrylate, perfluoro-n-butyl (meth)acrylate, perfluoro-1-butyl (meth)acrylate, perfluoro-t-butyl (meth)acrylate, perfluorocyclohexyl (meth)acrylate, 2-(1,1,1,3,3,3-hexafluoro)propyl (meth)acrylate, 1-(2,2,3,3,4,4,5,5-octafluoro)pentyl (meth)acrylate, 1-(2,2,3,3,4,4,5,5-octafluoro)hexyl (meth)acrylate, perfluorocyclohexylmethyl (meth)acrylate, 1-(2,2,3,3,3-pentafluoro)propyl (meth)acrylate, 1-(2,2,3,3,4,4,4-heptafluoro)penta (meth)acrylate, 1-(3,3,4,4,5,5,6,6,7,7,8,8,9,9,10,10,10-heptadecafluoro)decyl (meth)acrylate, 1-(5-trifluoromethyl-3,3,4,4,5,6,6,6-octafluoro)hexyl (meth)acrylate, and the like.

The resin (A) may further include a repeating unit (A6). The repeating unit (A6) is shown by the following formula (6).

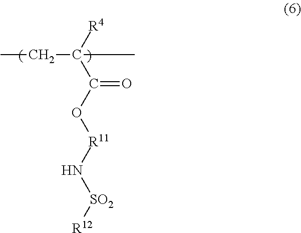

wherein R⁴ represents a hydrogen atom, a methyl group, or a trifluoromethyl group.

R¹¹ in the formula (6) preferably represents a methylene group, a linear or branched alkylene group having 2 to 20 carbon atoms, or a divalent cyclic hydrocarbon group, for example. Among these, a chain-like or cyclic hydrocarbon group, an alkylene glycol group, and an alkylene ester group are more preferable.

Preferable examples of R¹¹ include unsaturated chain-like hydrocarbon groups such as a methylene group, an ethylene group, a propylene group (e.g., 1,2-propylene group and 1,3-propylene group), a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; a cyclobutylene group (e.g., 1,3-cyclobutylene group); a cyclopentylene group (e.g., 1,3-cyclopentylene group); a cyclohexylene group (e.g., 1,4-cyclohexylene group); a divalent group derived from a monocyclic hydrocarbon group; a norbornylene group; a divalent group derived from a bridged cyclic hydrocarbon group; and the like.

Specific examples of the monocyclic hydrocarbon group include cycloalkylene groups having 3 to 10 carbon atoms. Specific examples of the cycloalkylene groups having 3 to 10 carbon atoms include a cyclooctylene group (e.g., 1,5-cyclooctylene group). Specific examples of the norbornylene group include a 1,4-norbornylane group and a 2,5-norbornylene group. Specific examples of the bridged cyclic hydrocarbon group include 2 to 4-membered cyclic hydrocarbon groups having 4 to 30 carbon atoms. Specific examples of the 2 to 4-membered cyclic hydrocarbon groups having 4 to 30 carbon atoms include an adamantylene group (e.g., 1,5-adamantylene group and 2,6-adamantylene group).

R¹² in the formula (6) preferably represents a trifluoromethyl group.

Specific examples of a preferable monomer that produces the repeating unit (A6) include (((trifluoromethyl)sulfonyl)amino)ethyl-1-methacrylate, 2-(((trifluoromethyl)sulfonyl)amino)ethyl-1-acrylate, and the monomers shown by the following formulas (6-1) to (6-6).

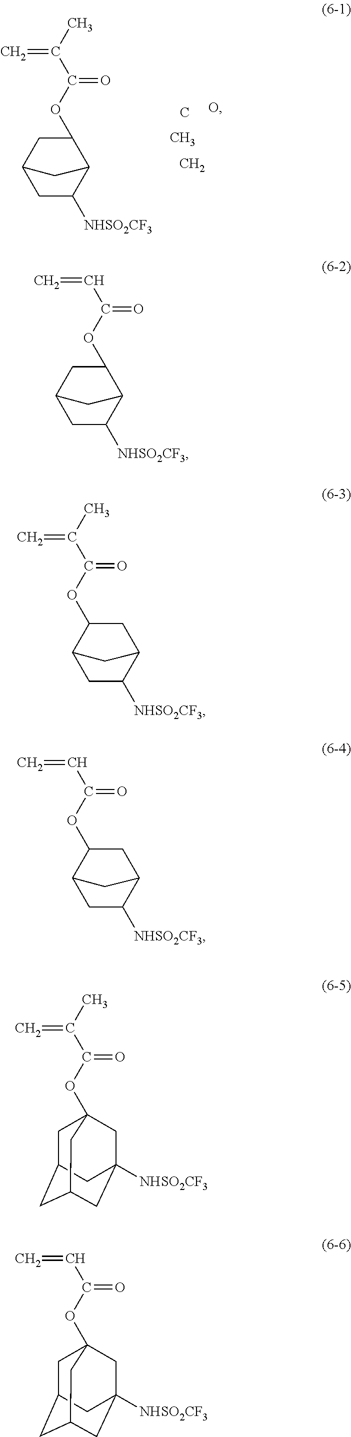

The polymer may further include at least one repeating unit other than the repeating units (A1) to (A6).

Preferable examples of the at least one repeating unit other than the repeating units (A1) to (A6) include repeating units shown by the following formulas (7-1) to (7-6) (hereinafter may be referred to as “repeating unit (A7)”) and a repeating unit shown by the following formula (8) (hereinafter may be referred to as “repeating unit (A8)”).

The repeating unit (A7) is shown by any of the following formulas (7-1) to (7-6).

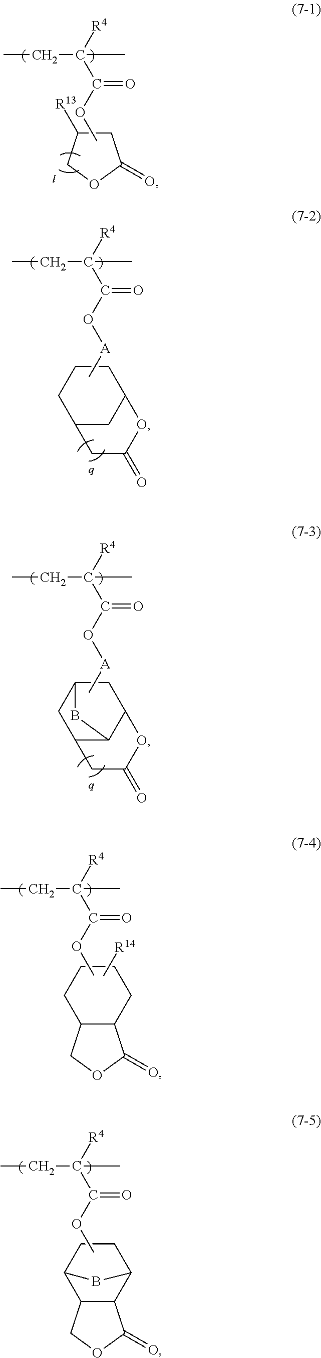

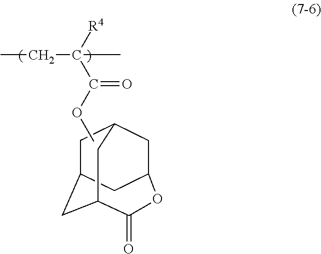

wherein R⁴ represents a hydrogen atom, a methyl group, or a trifluoromethyl group, R¹³ represents a hydrogen atom or a substituted or unsubstituted alkyl group having 1 to 4 carbon atoms, R¹⁴ represents a hydrogen atom or a methoxy group, A represents a single bond or a methylene group, B represents an oxygen atom or a methylene group, 1 is an integer from 1 to 3, and q is 0 or 1.

Examples of a preferable monomer that produces the repeating unit (A7) include 5-oxo-4-oxatricyclo[4.2.1.0^{3,7}]non-2-yl (meth)acrylate, 9-methoxycarbonyl-5-oxo-4-oxatricyclo[4.2.1.0^{3,7}]non-2-yl (meth)acrylate, 5-oxo-4-oxatricyclo[5.2.1.0^{3,8}]dec-2-yl (meth)acrylate, 10-methoxycarbonyl-5-oxo-4-oxatricyclo[5.2.1.0^{3,8}]non-2-yl (meth)acrylate, 6-oxo-7-oxabicyclo[3.2.1]oct-2-yl (meth)acrylate, 4-methoxycarbonyl-6-oxo-7-oxabicyclo[3.2.1]oct-2-yl(meth)acrylate, 7-oxo-8-oxabicyclo[3.3.1]oct-2-yl (meth)acrylate, 4-methoxycarbonyl-7-oxo-8-oxabicyclo[3.3.1]oct-2-yl (meth)acrylate, 2-oxotetrahydropyran-4-yl (meth)acrylate, 4-methyl-2-oxotetrahydropyran-4-yl (meth)acrylate, 4-ethyl-2-oxotetrahydropyran-4-yl (meth)acrylate, 4-propyl-2-oxotetrahydropyran-4-yl (meth)acrylate, 2-oxotetrahydrofuran-4-yl (meth)acrylate, 5,5-dimethyl-2-oxotetrahydrofuran-4-yl (meth)acrylate, 3,3-dimethyl-2-oxotetrahydrofuran-4-yl (meth)acrylate, 2-oxotetrahydrofuran-3-yl (meth)acrylate, 4,4-dimethyl-2-oxotetrahydrofuran-3-yl (meth)acrylate, 5,5-dimethyl-2-oxotetrahydrofuran-3-yl (meth)acrylate, 5-oxotetrahydrofuran-2-ylmethyl (meth)acrylate, 3,3-dimethyl-5-oxotetrahydrofuran-2-ylmethyl (meth)acrylate, and 4,4-dimethyl-5-oxotetrahydrofuran-2-ylmethyl (meth)acrylate.

The repeating unit (A8) is shown by the following formula (8).

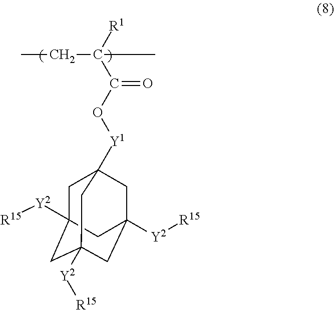

wherein R¹ represents a hydrogen atom or a methyl group, Y¹ represents a single bond or a divalent organic group having 1 to 3 carbon atoms, Y² individually represent a single bond or a divalent organic group having 1 to 3 carbon atoms, and R¹⁵ individually represent a hydrogen atom, a hydroxyl group, a cyano group, or —COOR¹⁶ (wherein R¹⁶ represents a hydrogen atom, a linear or branched alkyl group having 1 to 4 carbon atoms, or an alicyclic alkyl group having 3 to 20 carbon atoms). It is preferable that at least one of R¹⁵ does not represent a hydrogen atom, and at least one of Y² represents a divalent organic group having 1 to 3 carbon atoms when Y¹ represents a single bond.

In the repeating unit (A8) shown by the formula (8), Y¹ represents a single bond or a divalent organic group having 1 to 3 carbon atoms, and Y² individually represent a single bond or a divalent organic group having 1 to 3 carbon atoms. Examples of the divalent organic group having 1 to 3 carbon atoms represented by Y′ and Y² include a methylene group, an ethylene group, and a propylene group.

R¹⁶ in —COOR¹⁶ represented by R¹⁵ in the formula (8) represents a hydrogen atom, a linear or branched alkyl group having 1 to 4 carbon atoms, or an alicyclic alkyl group having 3 to 20 carbon atoms. Examples of the linear or branched alkyl group having 1 to 4 carbon atoms represented by R¹⁶ include a methyl group, an ethyl group, an n-propyl group, an i-propyl group, an n-butyl group, a 2-methylpropyl group, a 1-methylpropyl group, and a t-butyl group.

Examples of the alicyclic alkyl group having 3 to 20 carbon atoms represented by R¹⁶ include a cycloalkyl group shown by —CₙH₂ₙ₋₁ (wherein n is an integer from 3 to 20), a polyalicyclic alkyl group, and the like. Examples of the cycloalkyl group include a cyclopropyl group, a cyclobutyl group, a cyclopentyl group, a cyclohexyl group, a cycloheptyl group, a cyclooctyl group, and the like. Examples of the polyalicyclic alkyl group include a bicyclo[2.2.1]heptyl group, a tricyclo[5.2.1.0^{2,6}]decyl group, a tetracyclo[6.2.1^{3,6}.0^{2,7}]dodecanyl group, an adamantyl group, and the like. The cycloalkyl group and the polyalicyclic alkyl group may be substituted with at least one linear, branched, or cyclic alkyl group.

Examples of a preferable monomer that produces the repeating unit (A8) include 3-hydroxyadamant-1-yl (meth)acrylate, 3,5-dihydroxyadamantan-1-yl (meth)acrylate, 3-hydroxyadamantylmethyl(meth)acrylate, 3,5-dihydroxyadamantan-1-ylmethyl (meth)acrylate, 3-hydroxy-5-methyladamant-yl (meth)acrylate, 3,5-dihydroxy-7-methyladamant-1-yl (meth)acrylate, 3-hydroxy-5,7-dimethyladamant-1-yl (meth)acrylate, 3-hydroxy-5,7-dimethyladamant-1-ylmethyl (meth)acrylate, and the like.

When the resin (A) includes at least one repeating unit selected from the group consisting of the repeating units (A4) to (A8), the characteristics of the repeating units (A1) and (A2) can be sufficiently utilized. When the resin (A) includes at least one repeating unit selected from the group consisting of the repeating units (A4) to (A6), the resulting radiation-sensitive resin composition exhibits excellent performance as a chemically-amplified resist when used to form a fine pattern having a line width of 90 nm or less, or when used for liquid immersion lithography.

The polymer used as the resin (A) included in the radiation-sensitive resin composition according to one embodiment of the invention may further include an additional repeating unit other than the repeating units (A4) and (A8).

Examples of the additional repeating unit include units obtained by cleavage of a polymerizable unsaturated bond of a polyfunctional monomer such as (meth)acrylates having a bridged hydrocarbon skeleton, such as dicyclopentenyl (meth)acrylate, bicyclo[2.2.1]heptyl (meth)acrylate, cyclohexyl (meth)acrylate, bicyclo[4.4.0]decanyl (meth)acrylate, bicyclo[2.2.2]octyl (meth)acrylate, tricyclo[5.2.1.0^{2,6}]decanyl (meth)acrylate, tetracyclo[6.2.1.1^{3,6}.0^{2,7}]dodecanyl (meth)acrylate, tricyclo[3.3.1.1^{3,7}]decanyl (meth)acrylate, and adamantylmethyl (meth)acrylate; carboxyl group-containing esters having a bridged hydrocarbon skeleton of an unsaturated carboxylic acid, such as carboxylnorbonyl (meth)acrylate, carboxytricyclodecanyl (meth)acrylate, and carboxytetracycloundecanyl (meth)acrylate; (meth)acrylates that roes not have a bridged hydrocarbon skeleton, such as methyl (meth)acrylate, ethyl (meth)acrylate, n-propyl (meth)acrylate, n-butyl (meth)acrylate, 2-methylpropyl (meth)acrylate, 1-methylpropyl (meth)acrylate, t-butyl (meth)acrylate, 2-hydroxyethyl (meth)acrylate, 2-hydroxypropyl (meth)acrylate, 3-hydroxypropyl (meth)acrylate, cyclopropyl (meth)acrylate, cyclopentyl (meth)acrylate, cyclohexyl (meth)acrylate, 4-methoxycyclohexyl (meth)acrylate, 2-cyclopentyloxycarbonylethyl (meth)acrylate, 2-cyclohexyloxycarbonylethyl (meth)acrylate, and 2-(4-methoxycyclohexyl)oxycarbonylethyl (meth)acrylate; α-hydroxymethylacrylates such as methyl α-hydroxymethylacrylate, ethyl α-hydroxymethylacrylate, n-propyl α-hydroxymethylacrylate, and n-butyl α-hydroxymethylacrylate; unsaturated nitrile compounds such as (meth)acrylonitrile, α-chloroacrylonitrile, crotonitrile, maleinitrile, fumaronitrile, mesaconitrile, citraconitrile, and itaconitrile; unsaturated amide compounds such as (meth)acrylamide, N,N-dimethyl(meth)acrylamide, crotonamide, maleinamide, fumaramide, mesaconamide, citraconamide, and itaconamide; nitrogen-containing vinyl compounds such as N-(meth)acryloylmorpholine, N-vinyl-ε-caprolactam, N-vinylpyrrolidone, vinylpyridine, and vinylimidazole; unsaturated carboxylic acids (anhydrides) such as a (meth)acrylic acid, crotonic acid, maleic acid, maleic anhydride, fumaric acid, itaconic acid, itaconic anhydride, citraconic acid, citraconic anhydride, and mesaconic acid; carboxyl group-containing esters of unsaturated carboxylic acid that do not have a bridged hydrocarbon skeleton such as 2-carboxyethyl (meth)acrylate, 2-carboxypropyl (meth)acrylate, 3-carboxypropyl (meth)acrylate, 4-carboxybutyl (meth)acrylate, and 4-carboxycyclohexyl (meth)acrylate; polyfunctional monomers such as polyfunctional monomers having a bridged hydrocarbon skeleton such as 1,2-adamantanediol di(meth)acrylate, 1,3-adamantanediol di(meth)acrylate, 1,4-adamantanediol di(meth)acrylate, and tricyclodecanyldimethylol di(meth)acrylate; and polyfunctional monomers that do not have a bridged hydrocarbon skeleton, such as methylene glycol di(meth)acrylate, ethylene glycol di(meth)acrylate, propylene glycol di(meth)acrylate, 1,6-hexanediol di(meth)acrylate, 2,5-dimethyl-2,5-hexanediol di(meth)acrylate, 1,8-octanediol di(meth)acrylate, 1,9-nonanediol di(meth)acrylate, 1,4-bis(2-hydroxypropyl)benzene di(meth)acrylate, and 1,3-bis(2-hydroxypropyl)benzene di(meth)acrylate.

The content of the repeating unit (A1) in the polymer is preferably 10 to 85 mol %, more preferably 20 to 80 mol %, and particularly preferably 30 to 70 mol %, based on the total repeating units. This makes it possible to improve the developability, the defect resistance, the LWR, the PEB temperature dependence, and the like of a resist produced using the polymer as a resin component. If the content of the repeating unit (A1) is less than 10 mol %, the developability and the defect resistance of the resist may deteriorate. If the content of the repeating unit (A1) exceeds 85 mol %, the resolution, the LWR, and the PEB temperature dependency of the resist may deteriorate.

The content of the repeating unit (A2) in the polymer is preferably 10 to 85 mol %, more preferably 20 to 80 mol %, and particularly preferably 30 to 70 mol %, based on the total repeating units. This makes it possible to improve the developability, the defect resistance, the LWR, the PEB temperature dependence, and the like of the resulting resist. If the content of the repeating unit (A2) is less than 10 mol %, the resolution, the LWR, and the PEB temperature dependency of the resist may deteriorate. If the content of the repeating unit (A2) exceeds 85 mol %, the developability and the defect resistance of the resist may deteriorate.

The content of the repeating unit (A3) in the polymer is preferably 5 to 70 mol %, more preferably 5 to 60 mol %, and particularly preferably 10 to 50 mol %, based on the total repeating units. This makes it possible to improve the pattern collapse resistance, the resolution, the LWR, and the PEB temperature dependence, and the like of the resulting resist. If the content of the repeating unit (A3) is less than 5 mol %, the pattern collapse resistance of the resist may deteriorate. If the content of the repeating unit (A3) exceeds 70 mol %, the resolution, the LWR, and the PEB temperature dependence of the resist may deteriorate.

The repeating units (A4) to (A6) are preferably included in the polymer. The repeating units (A7) and (A8) are optional components.

The content of the repeating unit (A4) in the polymer is preferably 60 mol % or less, more preferably 5 to 60 mol %, still more preferably 5 to 50 mol %, and particularly preferably 10 to 40 mol %, based on the total repeating units. This makes it possible to improve the developability, the defect resistance, the LWR, the PEB temperature dependence, and the like of the resulting resist.

The content of the repeating unit (A5) in the polymer is preferably 30 mol % or less, more preferably 5 to 20 mol %, and particularly preferably 10 to 15 mol %, based on the total repeating units. This makes it possible to improve the pattern collapse resistance. If the content of the repeating unit (A5) exceeds 30 mol %, the resist pattern may undergo a top-loss phenomenon, so that the pattern shape may deteriorate.

The content of the repeating unit (A6) in the polymer is preferably 60 mol % or less, more preferably 50 mol % or less, and particularly preferably 40 mol % or less, based on the total repeating units.

The content of the repeating unit (A7) in the polymer is preferably 30 mol % or less, and more preferably 25 mol % or less, based on the total repeating units. If the content of the repeating unit (A7) exceeds 30 mol %, the defect resistance of the resulting resist may deteriorate.

The content of the repeating unit (A8) in the polymer is preferably 30 mol % or less, and more preferably 25 mol % or less, based on the total repeating units. If the content of the repeating unit (A8) exceeds 30 mol %, the resulting resist film may swell in an alkaline developer, or the developability of the resulting resist may deteriorate.

The content of the additional repeating unit other than the repeating units (A4) to (A8) in the polymer is preferably 50 mol % or less, and more preferably 40 mol % or less, based on the total repeating units.

The resin (A) may be a mixed resin of a first resin (AI) and a second resin (AII).

In this case, the resin (A) includes 100 parts by mass of the resin (AI), and 0.1 to 20 parts by mass of the resin (AII). It is preferable that the resin (AI) be a polymer that becomes alkali-soluble due to an acid, and does not include a fluorine atom, and the resin (AII) be a polymer that includes the repeating unit (A1) and a fluorine-containing repeating unit (A5). When the resin composition according to one embodiment of the invention includes the mixed resin, the resin composition exhibits excellent basic resist performance (e.g., resolution and LWR), and rarely produces defects (e.g., watermark defects and bubble defects) when subjected to liquid immersion lithography.

The first resin (AI) is a polymer that becomes alkali-soluble due to an acid, and does not include a fluorine atom. The expression “does not include a fluorine atom” used herein means that introduction (incorporation) of a fluorine atom into the resin (AI) is intentionally avoided during production. For example, a monomer that includes a fluorine atom is not used when producing (polymerizing) the polymer.

The resin (AI) becomes alkali-soluble due to an acid. Specifically, the resin (AI) is a polymer that includes a repeating unit having a structure that exhibits alkali-solubility due to an acid. Examples of such a repeating unit include a repeating unit that may be included in a polymer included in a radiation-sensitive resin composition. The repeating units (A2) and (A3) are preferable as such a repeating unit.

The resin (AI) preferably further include the repeating unit (A1), and may further include at least one of the repeating units (A4), (A6), (A7), and (A8) and the additional repeating unit.

The resin composition according to one embodiment of the invention may include only one type of resin (AI), or may include two or more types of resins (AI).

The total content of the repeating units (A2) and (A3) in the resin (AI) is preferably 10 to 90 mol %, more preferably 20 to 80 mol %, and particularly preferably 30 to 70 mol %, based on the total repeating units. This makes it possible to improve the developability, the defect resistance, the LWR, the PEB temperature dependence, and the like of the resulting resist. If the total content of the repeating units (A2) and (A3) is less than 10 mol %, the developability, the LWR, and the PEB temperature dependency of the resist may deteriorate. If the total content of the repeating units (A2) and (A3) exceeds 90 mol %, the developability and the defect resistance of the resist may deteriorate.

The content of the repeating unit (A7) in the resin (AI) is preferably 10 to 70 mol %, more preferably 15 to 65 mol %, and particularly preferably 20 to 60 mol %, based on the total repeating units. This makes it possible to improve the developability of the resulting resist.

The second resin (AII) is a polymer that includes the repeating units (A1) and (A5).

The resin (AII) may further include at least one of the repeating units (A2), (A3), (A4), (A6), (A7), and (A8) and the additional repeating unit.

The resin composition according to one embodiment of the invention may include only one type of resin (AII) (second resin (polymer)), or may include two or more types of resins (AII) (second resins (polymers)).

The content of the repeating unit (A1) in the resin (AII) is preferably 5 to 60 mol %, more preferably 5 to 50 mol %, and particularly preferably 10 to 40 mol %, based on the total repeating units. This makes it possible to improve the defect resistance and the scan capability during exposure. If the content of the repeating unit (A1) is less than 10 mol %, the developability and the defect resistance of the resist may deteriorate. If the content of the repeating unit (A1) exceeds 60 mol %, the scan capability during exposure may deteriorate.

The content of the repeating unit (A5) in the resin (AII) is preferably 10 to 80 mol %, more preferably 20 to 80 mol %, and particularly preferably 20 to 70 mol %, based on the total repeating units. This makes it possible to improve the defect resistance and the scan capability during exposure. If the content of the repeating unit (A5) is less than 10 mol %, the defect resistance and the scan capability during exposure may deteriorate. If the content of the repeating unit (A5) exceeds 80 mol %, the defect resistance may deteriorate.

The content of the additional repeating unit other than the repeating units (A1) and (A5) in the resin (AII) is preferably 30 mol % or less based on the total repeating units.

When the radiation-sensitive resin composition according to one embodiment of the invention includes the resins (AI) and (AII), the content (solid content) of the resin (AII) in the radiation-sensitive resin composition is preferably 0.1 to 20 parts by mass, more preferably 0.1 to 15 parts by mass, and particularly preferably 0.5 to 15 parts by mass, based on 100 parts by mass of the resin (AI). If the content of the resin (AII) is within the above range, the fluorine-containing resin (AII) advantageously exhibits its effect. When using the composition for liquid immersion lithography, the surface of the resist film exhibits water repellency, and watermark defects do not occur due to a high-speed scan during liquid immersion lithography. As a result, a resist pattern having an excellent shape is obtained.

A method of producing each polymer is described below.

Each polymer may be synthesized by radical polymerization or the like. Each polymer may preferably be produced (polymerized) as follows, for example. (1) Monomers are polymerized while adding a reaction solution containing monomers and a radical initiator dropwise to a reaction solvent or a reaction solution containing monomers. (2) Monomers are polymerized while adding a reaction solution containing monomers and a reaction solution containing a radical initiator dropwise to a reaction solvent or a reaction solution containing monomers. (3) Monomers are polymerized while adding a plurality of reaction solutions respectively containing different types of monomers and a reaction solution containing a radical initiator dropwise to a reaction solvent or a reaction solution containing monomers.

The reaction temperature employed for each reaction may be appropriately determined depending on the type of initiator, but is normally 30 to 180° C., for example. The reaction temperature is preferably 40 to 160° C., and more preferably 50 to 140° C. The dropwise addition time may be appropriately determined depending on the reaction temperature, the type of initiator, and the type of monomer, but is preferably 30 minutes to 8 hours, more preferably 45 minutes to 6 hours, and particularly preferably 1 to 5 hours. The total reaction time including the dropwise addition time may be appropriately determined depending on the reaction temperature, the type of initiator, and the type of monomer, but is preferably 30 minutes to 8 hours, more preferably 45 minutes to 7 hours, and particularly preferably 1 to 6 hours. When adding a monomer solution dropwise to another monomer solution, the content of monomers in the monomer solution added to the other monomer solution is preferably 30 mol % or more, more preferably 50 mol % or more, and particularly preferably 70 mol % or more, based on the total amount of monomers subjected to polymerization.

Examples of the radical initiator used for polymerization include 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis-iso-butylonitrile, 2,2′-azobis(2-methylbutyronitrile), 1,1′-azobis(cyclohexane-1-carbonitrile), 2,2′-azobis(2-methyl-N-phenylpropioneamidine)dihydrochloride, 2,2′-azobis(2-methyl-N-2-propenylpropioneamidine)dihydrochloride, 2,2′-azobis[2-(5-methyl-2-imidazolin-2-yl)propane]dihydrochloride, 2,2′-azobis[2-methyl-N-[1,1-bis(hydroxymethyl)-2-hydroxyethyl]propioneamide], dimethyl-2,2′-azobis(2-methylpropionate), 4,4′-azobis(4-cyanovaleric acid), 2,2′-azobis(2-(hydroxymethyl)propionitrile), and the like. These initiators may be used either individually or in combination.

A solvent that dissolves the monomers and does not hinder polymerization may be used as the polymerization solvent. Examples of a solvent that hinders polymerization include a solvent that inhibits polymerization (e.g., nitrobenzene), a solvent that causes a chain transfer (e.g., mercapto compound), and the like.

Examples of a solvent that may suitably be used for polymerization include alcohols, ethers, ketones, amides, esters, lactones, nitriles, and a mixture thereof. Examples of the alcohols include methanol, ethanol, propanol, isopropanol, butanol, ethylene glycol, propylene glycol, ethylene glycol monomethyl ether, ethylene glycol monoethyl ether, and 1-methoxy-2-propanol. Examples of the ethers include propyl ether, isopropyl ether, butyl methyl ether, tetrahydrofuran, 1,4-dioxane, 1,3-dioxolane, and 1,3-dioxane. Examples of the ketones include acetone, methyl ethyl ketone, diethyl ketone, methyl isopropyl ketone, and methyl isobutyl ketone. Examples of the amides include N,N-dimethylformamide and N,N-dimethylacetamide. Examples of the esters and the lactones include ethyl acetate, methyl acetate, isobutyl acetate, and γ-butyrolactone. Examples of the nitriles include acetonitrile, propionitrile, and butyronitrile. These solvents may be used either individually or in combination.

The polymer obtained by polymerization is preferably collected by re-precipitation. Specifically, the reaction solution is poured into a re-precipitation solvent after polymerization to collect the target resin as a powder. Examples of the re-precipitation solvent include water, alcohols, ethers, ketones, amides, esters, lactones, nitriles, and a mixture thereof. Examples of the alcohols include methanol, ethanol, propanol, isopropanol, butanol, ethylene glycol, propylene glycol, and 1-methoxy-2-propanol. Examples of the ethers include propyl ether, isopropyl ether, butyl methyl ether, tetrahydrofuran, 1,4-dioxane, 1,3-dioxolane, and 1,3-dioxane. Examples of the ketones include acetone, methyl ethyl ketone, diethyl ketone, methyl isopropyl ketone, and methyl isobutyl ketone. Examples of the amides include N,N-dimethylformamide and N,N-dimethylacetamide. Examples of the esters and the lactones include ethyl acetate, methyl acetate, isobutyl acetate, and γ-butyrolactone. Examples of the nitriles include acetonitrile, propionitrile, and butyronitrile.

The content of low-molecular-weight components derived from monomers in the polymer is preferably 0.1 mass % or less, more preferably 0.07 mass % or less, and particularly preferably 0.05 mass % or less, based on the total amount (100 mass %) of the polymer.

If the content of low-molecular-weight components is 0.1 mass % or less, it is possible to reduce the amount of eluate into water when performing liquid immersion lithography using a resist film produced using the resin (A). Moreover, it is possible to prevent a situation in which foreign matter is produced in the resist during storage, prevent non-uniform resist application, and sufficiently suppress occurrence of defects when forming a resist pattern.

The term “low-molecular-weight components derived from monomers” used herein refer to monomers, dimers, trimers, and oligomers having a polystyrene-reduced weight average molecular weight (Mw) determined by gel permeation chromatography (GPC) of 500 or less. Components having an Mw of 500 or less may be removed by chemical purification (e.g., washing with water or liquid-liquid extraction), or a combination of chemical purification and physical purification (e.g., ultrafiltration or centrifugation), for example.

The amount of low-molecular-weight components may be determined by analyzing the polymer by high-performance liquid chromatography (HPLC). It is preferable that the impurity (e.g., halogen and metal) content in the polymer (resin (A)) be as low as possible. The sensitivity, the resolution, the process stability, the pattern shape, and the like of the resulting resist can be improved by reducing the impurity content in the polymer.

The polystyrene-reduced weight average molecular weight (Mw) of the polymer determined by gel permeation chromatography (GPC) is not particularly limited, but is preferably 1000 to 100,000, more preferably 1000 to 30,000, and particularly preferably 1000 to 20,000. If the Mw of the polymer is less than 1000, the heat resistance of the resulting resist may deteriorate. If the Mw of the polymer exceeds 100,000, the developability of the resulting resist may deteriorate. The ratio (Mw/Mn) of the Mw to the polystyrene-reduced number average molecular weight (Mn) of the polymer determined by GPC is preferably 1.0 to 5.0, more preferably 1.0 to 3.0, and particularly preferably 1.0 to 2.0.

The radiation-sensitive resin composition according to one embodiment of the invention may include only one type of polymer, or may include two or more of types of polymer.

### Photoacid Generator (B)

The photoacid generator (B) (hereinafter may be referred to as “acid generator (B)”) included in the radiation-sensitive resin composition according to one embodiment of the invention generates an acid upon exposure. The acid generator causes the acid-dissociable group of the resin (A) included in the radiation-sensitive resin composition to dissociate (causes elimination of a protective group) due to an acid generated upon exposure so that the resin (A) becomes alkali-soluble. As a result, the exposed area of the resist film becomes readily soluble in an alkaline developer. This makes it possible to form a positive-tone resist pattern.

The acid generator (B) is preferably an acid generator (B1) that includes a compound shown by the following formula (9).

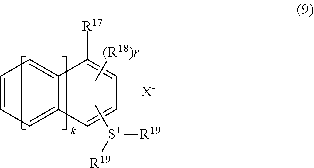

In the formula (9), R¹⁷ represents a hydrogen atom, a fluorine atom, a hydroxyl group, a linear or branched alkyl group having 1 to 10 carbon atoms, a linear or branched alkoxy group having 1 to 10 carbon atoms, or a linear or branched alkoxycarbonyl group having 2 to 11 carbon atoms.

R¹⁸ represents a linear or branched alkyl group having 1 to 10 carbon atoms, an alkoxy group having 1 to 10 carbon atoms, or a linear, branched, or cyclic alkanesulfonyl group having 1 to 10 carbon atoms. r is an integer from 0 to 10, and preferably an integer from 0 to 2.

R¹⁹ individually represent a linear or branched alkyl group having 1 to 10 carbon atoms, a substituted or unsubstituted phenyl group, or a substituted or unsubstituted naphtyl group, or bond to each other to form a substituted or unsubstituted divalent group having 2 to 10 carbon atoms. k is an integer from 0 to 2.

X⁻ represents an anion shown by the following formula (10-1), (10-2), (10-3), or (10-4).

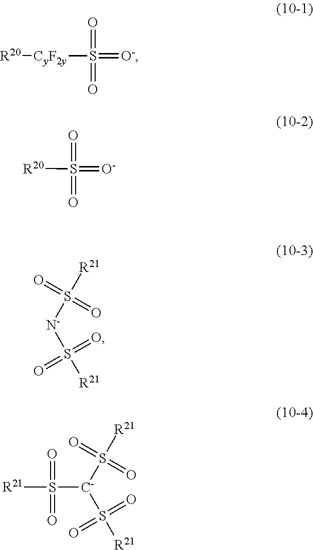

In the formulas (10-1) and (10-2), R²⁰ represents a hydrogen atom, a fluorine atom, or a substituted or unsubstituted hydrocarbon group having 1 to 12 carbon atoms. y is an integer from 1 to 10.

In the formulas (10-3) and (10-4), R²¹ individually represent a linear or branched fluoroalkyl group having 1 to 10 carbon atoms, provided that two of R²¹ may bond to each other to form a substituted or unsubstituted divalent fluorine-containing group having 2 to 10 carbon atoms.

Examples of the linear or the branched alkyl group having 1 to 10 carbon atoms represented by R¹⁷, R¹⁸, and R¹⁹ in the formula (9) include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among these, a methyl group, an ethyl group, an n-butyl group, a t-butyl group, and the like are preferable.

Examples of the linear or branched alkoxy group having 1 to 10 carbon atoms represented by R¹⁷ and R¹⁸ include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. Among these, a methoxy group, an ethoxy group, an n-propoxy group, a n-butoxy group, and the like are preferable.

Examples of the linear or branched alkoxycarbonyl group having 2 to 11 carbon atoms represented by R¹⁷ include a methoxycarbonyl group, an ethoxycarbonyl group, an n-propoxycarbonyl group, an i-propoxycarbonyl group, an n-butoxycarbonyl group, a 2-methylpropoxycarbonyl group, an 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among these, a methoxycarbonyl group, an ethoxycarbonyl group, an n-butoxycarbonyl group, and the like are preferable.

Examples of the linear, branched, or cyclic alkanesulfonyl group having 1 to 10 carbon atoms represented by R¹⁸ include a methanesulfonyl group, an ethanesulfonyl group, an n-propanesulfonyl group, an n-buthanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, and the like. Among these, a methanesulfonyl group, an ethanesulfonyl group, an n-propanesulfonyl group, an n-butanesulfonyl group, a cyclopentansulfonyl group, a cyclohexanesulfonyl group, and the like are preferable.

Examples of the substituted or unsubstituted phenyl group represented by R¹⁹ in the formula (9) include a phenyl group; a phenyl group substituted with a linear, branched, or cyclic alkyl group having 1 to 10 carbon atoms, such as an o-tolyl group, an m-tolyl group, a p-tolyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4,6-trimethylphenyl group, a 4-ethylphenyl group, a 4-t-butylphenyl group, a 4-cyclohexylphenyl group, or a 4-fluorophenyl group; a group obtained by substituting a phenyl group or the alkyl-substituted phenyl group with at least one group selected from a hydroxyl group, a carboxyl group, a cyano group, a nitro group, an alkoxy group, an alkoxyalkyl group, an alkoxycarbonyl group, and an alkoxycarbonyloxy group; and the like.

Examples of the alkoxy group as a substituent for a phenyl group or the alkyl-substituted phenyl group include linear, branched, or cyclic alkoxy groups having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group, and the like.

Examples of the alkoxyalkyl group include linear, branched, or cyclic alkoxyalkyl groups having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group. Examples of the alkoxycarbonyl group include linear, branched, or cyclic alkoxycarbonyl groups having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, and a cyclohexyloxycarbonyl group.

Examples of the alkoxycarbonyloxy group include linear, branched, or cyclic alkoxycarbonyloxy groups having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyl group, and a cyclohexyloxycarbonyl group, and the like.

The substituted or unsubstituted phenyl group represented by R¹⁹ in the formula (9) is preferably a phenyl group, a 4-cyclohexylphenyl group, a 4-t-butylphenyl group, a 4-methoxyphenyl group, a 4-t-butoxyphenyl group, or the like.

Examples of the substituted or unsubstituted naphthyl group represented by R¹⁹ include a naphthyl group (e.g., 1-naphthyl group); a naphthyl group substituted with a linear, branched, or cyclic alkyl group having 1 to 10 carbon atoms, such as a 2-methyl-1-naphthyl group, a 3-methyl-1-naphthyl group, a 4-methyl-1-naphthyl group, a 5-methyl-1-naphthyl group, a 6-methyl-1-naphthyl group, a 7-methyl-1-naphthyl group, a 8-methyl-1-naphthyl group, a 2,3-dimethyl-1-naphthyl group, a 2,4-dimethyl-1-naphthyl group, a 2,5-dimethyl-1-naphthyl group, a 2,6-dimethyl-1-naphthyl group, a 2,7-dimethyl-1-naphthyl group, a 2,8-dimethyl-1-naphthyl group, a 3,4-dimethyl-1-naphthyl group, a 3,5-dimethyl-1-naphthyl group, a 3,6-dimethyl-1-naphthyl group, a 3,7-dimethyl-1-naphthyl group, a 3,8-dimethyl-1-naphthyl group, a 4,5-dimethyl-1-naphthyl group, a 5,8-dimethyl-1-naphthyl group, a 4-ethyl-1-naphthyl group, a 2-naphthyl group, a 1-methyl-2-naphthyl group, a 3-methyl-2-naphthyl group, and a 4-methyl-2-naphthyl group; a group obtained by substituting a naphthyl group or the alkyl-substituted naphthyl group with at least one group selected from a hydroxyl group, a carboxyl group, a cyano group, a nitro group, an alkoxy group, an alkoxyalkyl group, an alkoxycarbonyl group, and an alkoxycarbonyloxy group; and the like.

Examples of the alkoxy group, the alkoxyalkyl group, the alkoxycarbonyl group, and the alkoxycarbonyloxy group as a substituent include the groups mentioned above in connection with a phenyl group and the alkyl-substituted phenyl group.

The substituted or unsubstituted naphthyl group represented by R¹⁹ in the formula (9) is preferably a 1-naphthyl group, a 1-(4-methoxynaphthyl) group, a 1-(4-ethoxynaphthyl) group, a 1-(4-n-propoxynaphthyl) group, a 1-(4-n-butoxynaphthyl) group, a 2-(7-methoxynaphthyl) group, a 2-(7-ethoxynaphthyl) group, a 2-(7-n-propoxynaphthyl) group, a 2-(7-n-butoxynaphthyl) group, or the like.

The divalent group having 2 to 10 carbon atoms formed when two R¹⁹ bond to each other is preferably a group that forms a 5 or 6-membered ring (particularly preferably a 5-membered ring (i.e., tetrahydrothiophene ring)) together with the sulfur atom in the formula (9). Examples of the substituent for the divalent group include the groups mentioned as the substituents for a phenyl group and the alkyl-substituted phenyl group, such as a hydroxyl group, a carboxyl group, a cyano group, a nitro group, an alkoxy group, an alkoxyalkyl group, an alkoxycarbonyl group, and an alkoxycarbonyloxy group.

It is preferable that R¹⁹ in the formula (9) represent a methyl group, an ethyl group, a phenyl group, a 4-methoxyphenyl group, or a 1-naphthyl group, or two of R¹⁹ bond to each other to form a divalent group having a tetrahydrothiophene ring structure together with the sulfur atom, for example.

Examples of a preferable cation moiety in the formula (9) include a triphenylsulfonium cation, a tri-1-naphthylsulfonium cation, a tri-tert-butylphenylsulfonium cation, a 4-fluorophenyldiphenylsulfonium cation, a di-4-fluorophenylphenylsulfonium cation, a tri-4-fluorophenylsulfonium cation, a 4-cyclohexylphenyldiphenylsulfonium cation, a 4-methanesulfonylphenyldiphenylsulfonium cation, a 4-cyclohexanesulfonyldiphenylsulfonium cation, a 1-naphthyldimethylsulfonium cation, a 1-naphthyldiethyl sulfonium cation, a 1-(4-hydroxynaphthalen-1-yl)dimethylsulfonium cation, a 1-(4-methylnaphthalen-1-yl)dimethylsulfonium cation, a 1-(4-methylnaphthalen-1-yl)diethylsulfonium cation, a 1-(4-cyanonaphthalen-1-yl)dimethylsulfonium cation, a 1-(4-cyanonaphthalen-1-yl)diethylsulfonium cation, a 1-(3,5-dimethyl-4-hydroxyphenyl)tetrahydrothiophenium cation, a 1-(4-methoxynaphthalen-1-yl)tetrahydrothiophenium cation, a 1-(4-ethoxynaphthalen-1-yl)tetrahydrothiophenium cation, a 1-(4-n-propoxynaphthalen-1-yl)tetrahydrothiophenium cation, a 1-(4-n-butoxynaphthalen-1-yl)tetrahydrothiophenium cation, a 2-(7-methoxynaphthalen-2-yl)tetrahydrothiophenium cation, a 2-(7-ethoxynaphthalen-2-yl)tetrahydrothiophenium cation, a 2-(7-n-propoxynaphthalen-2-yl)tetrahydrothiophenium cation, a 2-(7-n-butoxynaphthalen-2-yl)tetrahydrothiophenium cation, and the like.

X⁻ in the formula (9) represents an anion shown by the formula (10-1), (10-2), (10-3), or (10-4).

The CₙF₂ₙ group represents a linear or branched perfluoroalkyl group having n carbon atoms. n is preferably 1, 2, 4, or 8.

The substituted or unsubstituted hydrocarbon group having 1 to 12 carbon atoms represented by R²⁰ is preferably an alkyl group having 1 to 12 carbon atoms, a cycloalkyl group having 1 to 12 carbon atoms, or a bridge alicyclic hydrocarbon group having 1 to 12 carbon atoms. Specific examples of the hydrocarbon group having 1 to 12 carbon atoms represented by R²⁰ include a methyl group, an ethyl group, an n-propyl group, an i-propyl group, an n-butyl group, a 2-methylpropyl group, a 1-methylpropyl group, a t-butyl group, an n-pentyl group, an neopentyl group, an n-hexyl group, a cyclohexyl group, an n-heptyl group, an n-octyl group, a 2-ethylhexyl group, an n-nonyl group, an n-decyl group, a norbornyl group, a norbornylmethyl group, a hydroxynorbornyl group, an adamantyl group, and the like.

Examples of the linear or branched fluoroalkyl group having 1 to 10 carbon atoms represented by R²¹ include a trifluoromethyl group, a pentafluoroethyl group, a heptafuluoropropyl group, a nonafluorobutyl group, a dodecafluoropentyl group, a perfluorooctyl group, and the like.

Examples of the divalent fluorine-containing group having 2 to 10 carbon atoms that includes two R²¹ include a tetrafluoroethylene group, a hexafluoropropylene group, an octafluorobutylene group, a decafluoropentylene group, an undecafluorohexylene group, and the like.

Examples of a preferable anion moiety in the formula (9) include a trifluoromethanesulfonate anion, a perfluoro-n-butanesulfonate anion, a perfluoro-n-octanesulfonate anion, a 2-bicyclo[2.2.1]hept-2-yl-1,1,2,2-tetrafluoroethanesulfonate anion, a 2-bicyclo[2.2.1]hept-2-yl-1,1-difluoroethanesulfonate anion, a 1-adamantylsulfonate anion, anions shown by the following formulas (11-1) to (11-7), and the like.

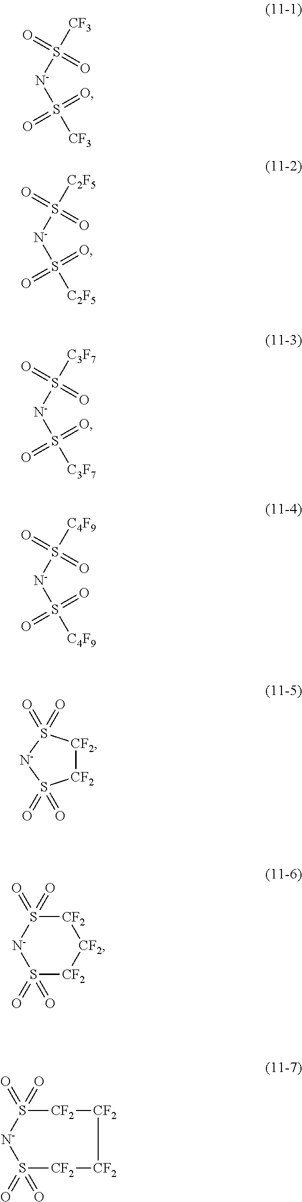

The acid generator (B1) includes the above cation and anion in an arbitrary combination. Only one type of acid generator (B1) may be used, or a plurality of acid generators (B1) may be used in combination.

Examples of a photoacid generator (hereinafter referred to as “additional acid generator”) other than the acid generator (B1) that may be included in the radiation-sensitive resin composition according to one embodiment of the invention include onium salt compounds, halogen-containing compounds, diazoketone compounds, sulfone compounds, sulfonic acid compounds, and the like. Examples of the additional acid generator are given below.

Examples of the onium salt compounds include iodonium salts, sulfonium salts, phosphonium salts, diazonium salts, pyridinium salts, and the like. Specific examples of the onium salt compounds include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, cyclohexyl.2-oxocyclohexyl.methylsulfonium trifluoromethanesulfonate, dicyclohexyl.2-oxocyclohexylsulfonium trifluoromethanesulfonate, 2-oxocyclohexyldimethylsulfonium trifluoromethanesulfonate, and the like.

Examples of the halogen-containing compounds include haloalkyl group-containing hydrocarbon compounds, haloalkyl group-containing heterocyclic compounds, and the like. Specific examples of the halogen-containing compounds include (trichloromethyl)-s-triazine derivatives such as phenylbis(trichloromethyl)-s-triazine, 4-methoxyphenylbis(trichloromethyl)-s-triazine, 1-naphthylbis(trichloromethyl)-s-triazine, 1,1-bis(4-chlorophenyl)-2,2,2-trichloroethane, and the like.

Examples of the diazoketone compounds include 1,3-diketo-2-diazo compounds, diazobenzoquinone compounds, diazonaphthoquinone compounds, and the like. Specific examples of the diazoketone compounds include 1,2-naphthoquinonediazido-4-sulfonyl chloride, 1,2-naphthoquinonediazido-5-sulfonyl chloride, 1,2-naphthoquinonediazido-4-sulfonate or 1,2-naphthoquinonediazido-5-sulfonate of 2,3,4,4′-tetrahydroxybenzophenone, 1,2-naphthoquinonediazido-4-sulfonate or 1,2-naphthoquinonediazido-5-sulfonate of 1,1,1-tris(4-hydroxyphenyl)ethane, and the like.

Examples of the sulfone compounds include β-ketosulfone, β-sulfonylsulfone, α-diazo compounds thereof, and the like. Specific examples of the sulfone compounds include 4-trisphenacylsulfone, mesitylphenacylsulfone, bis(phenylsulfonyl)methane, and the like.

Examples of the sulfonic acid compounds include alkyl sulfonates, alkylimide sulfonates, haloalkyl sulfonates, aryl sulfonates, imino sulfonates, and the like. Specific examples of the sulfonic acid compounds include benzointosylate, tris(trifluoromethanesulfonate) of pyrogallol, nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, 2-bicyclo[2.2.1]hept-2-yl-1,1,2,2-tetrafluoroethanesulfonylbicyclo[2.2.1]hept-5-ene-2,3-dicarbodiimide, N-(trifluoromethanesulfonyloxy)succinimide, N-(nonafluoro-n-butanesulfonyloxy)succinimide, N-(perfluoro-n-octanesulfonyloxy)succinimide, N-(2-bicyclo[2.2.1]hept-2-yl-1,1,2,2-tetrafluoroethanesulfonyloxy)succinimide, 1,8-naphthalenedicarboxylic acid imide trifluoromethanesulfonate, 1,8-naphthalenedicarboxylic acid imide nonafluoro-n-butanesulfonate, 1,8-naphthalenedicarboxylic acid imide perfluoro-n-octanesulfonate, and the like.

These acid generators may be used either individually or in combination.

The total content of the acid generator (B1) and the additional acid generator in the radiation-sensitive resin composition according to one embodiment of the invention is preferably 0.1 to 20 parts by mass, and more preferably 0.5 to 10 parts by mass, based on 100 parts by mass of the resin (A), so that the resulting resist exhibits sufficient sensitivity and developability. If the total content of the acid generator (B1) and the additional acid generator is less than 0.1 parts by mass, the sensitivity and the developability may deteriorate. If the total content of the acid generator (B1) and the additional acid generator exceeds 20 parts by mass, a rectangular resist pattern may not be obtained due to a decrease in radiation transmittance. The content of the additional acid generator in the radiation-sensitive resin composition is preferably 80 mass % or less, and more preferably 60 mass % or less, based on the total amount of the acid generator (B1) and the additional acid generator.

### Nitrogen-Containing Compound (C)

The radiation-sensitive resin composition according to one embodiment of the invention may further include the nitrogen-containing compound (C) in addition to the resin (A) and the photoacid generator (B). The nitrogen-containing compound (C) controls a phenomenon in which an acid generated by the acid generator upon exposure is diffused in the resist film, and suppresses undesired chemical reactions in the unexposed area. Specifically, the nitrogen-containing compound (C) functions as an acid diffusion controller. The nitrogen-containing compound (C) improves the storage stability of the resulting radiation-sensitive resin composition, improves the resolution of the resulting resist, and suppresses a change in line width of the resist pattern due to a change in post-exposure delay (PED) from exposure to post-exposure bake. This makes it possible to obtain a composition that exhibits excellent process stability.

For example, a nitrogen-containing compound (c1) shown by the following formula (12) may suitably be used as the nitrogen-containing compound (C).

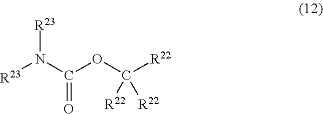

wherein R²² and R²³ individually represent a hydrogen atom, a substituted or unsubstituted linear, branched, or cyclic alkyl group having 1 to 20 carbon atoms, an aryl group, or an aralkyl group, provided that R²² or R²³ may bond to each other to form a saturated or unsaturated divalent hydrocarbon group having 4 to 20 carbon atoms, or a derivative thereof, together with the carbon atom bonded thereto.

Examples of the nitrogen-containing compound (c1) shown by the formula (12) include N-t-butoxycarbonyl group-containing amino compounds such as N-t-butoxycarbonyl-di-n-octylamine, N-t-butoxycarbonyl-di-n-nonylamine, N-t-butoxycarbonyl-di-n-decylamine, N-t-butoxycarbonyl dicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidinemethanol, (R)-(+)-1-(t-butoxycarbonyl)-2-pyrrolidinemethanol, R-(+)-1-(t-butoxycarbonyl)-2-piperidinemethanol, N-t-butoxycarbonyl-4-hydroxypiperidine, N-t-butoxycarbonylpyrrolidine, N,N′-di-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′,N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, and N-t-butoxycarbonyl-2-phenylbenzimidazole, and the like.

Further examples of the nitrogen-containing compound (C) include tertiary amine compounds, quaternary ammonium hydroxide compounds, photodegradable base compounds, nitrogen-containing heterocyclic compounds, and the like.

Examples of the tertiary amine compounds include tri(cyclo)alkylamines such as triethylamine, tri-n-propylamine, tri-n-butylamine, tri-n-pentylamine, tri-n-hexylamine, tri-n-heptylamine, tri-n-octylamine, cyclohexyl dimethylamine, dicyclohexyl methylamine, and tricyclohexylamine; aromatic amines such as aniline, N-methylaniline, N,N-dimethylaniline, 2-methylaniline, 3-methylaniline, 4-methylaniline, 4-nitroaniline, 2,6-dimethylaniline, and 2,6-diisopropylaniline; alkanolamines such as triethanolamine and N,N-di(hydroxyethyl)aniline; N,N,N′,N′-tetramethylethylenediamine, N,N,N′,N′-tetrakis(2-hydroxypropyl)ethylenediamine, 1,3-bis[1-(4-aminophenyl)-1-methylethyl]benzenetetramethylenediamine, bis(2-dimethylaminoethyl)ether, bis(2-diethylaminoethyl)ether, and the like.

Examples of the quaternary ammonium hydroxide compounds include tetra-n-propylammonium hydroxide, tetra-n-butylammonium hydroxide, and the like.

The photodegradable base compound is an onium salt compound that decomposes upon exposure, and loses basicity (i.e., acid diffusion controllability).

Specific examples of the onium salt compound include sulfonium salt compounds shown by the following formula (13-1) and iodonium salt compounds shown by the following formula (13-2).

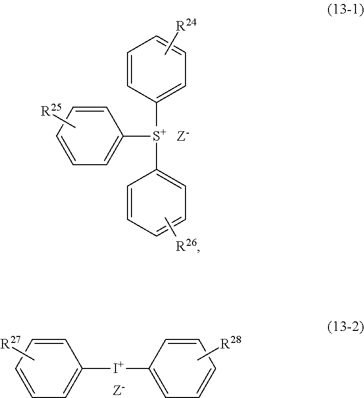

wherein R²⁴ to R²⁸ individually represent a hydrogen atom, an alkyl group, an alkoxyl group, a hydroxyl group, or a halogen atom.

Z⁻ represents OH⁻, R—COO⁻, R—SO₃⁻ (wherein R represents an alkyl group, an aryl group, or an alkaryl group), or an anion shown by the following formula (14).

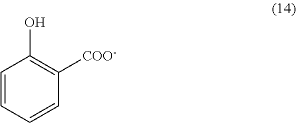

Specific examples of the sulfonium salt compound and the iodonium salt compound include triphenylsulfonium hydroxide, triphenylsulfonium acetate, triphenylsulfonium salicylate, diphenyl-4-hydroxyphenylsulfonium hydroxide, diphenyl-4-hydroxyphenylsulfonium acetate, diphenyl-4-hydroxyphenylsulfonium salicylate, bis(4-t-butylphenyl)iodonium hydroxide, bis(4-t-butylphenyl)iodonium acetate, bis(4-t-butylphenyl)iodonium hydroxide, bis(4-t-butylphenyl)iodonium acetate, bis(4-t-butylphenyl)iodonium salicylate, 4-t-butylphenyl-4-hydroxyphenyl)iodonium hydroxide, 4-t-butylphenyl-4-hydroxyphenyl)iodonium acetate, 4-t-butylphenyl-4-hydroxyphenyl)iodonium salicylate, bis(4-t-butylphenyl)iodonium 10-camphorsulfonate, diphenyliodonium 10-camphorsulfonate, triphenylsulfonium 10-camphorsulfonate, 4-t-butoxyphenyldiphenylsulfonium 10-camphorsulfonate, and the like.

Examples of the nitrogen-containing heterocyclic compounds include pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, and acridine; piperazines such as piperazine, 1-(2-hydroxyethyl)piperazine; pyrazine, pyrazole, pyridazine, quinoxaline, purine, pyrrolidine, piperidine, 3-piperidino-1,2-propanediol, morpholine, 4-methylmorpholine, 1,4-dimethylpiperazine, 1,4-diazabicyclo[2.2.2]octane, imidazole, 4-methylimidazole, 1-benzyl-2-methylimidazole, 4-methyl-2-phenylmidazole, benzimidazole, 2-phenylbenzimidazole, and the like.

These nitrogen-containing compounds (C) may be used either individually or in combination.

The content of the nitrogen-containing compound (C) in the radiation-sensitive resin composition according to one embodiment of the invention is preferably less than 10 parts by mass, and more preferably less than 5 parts by mass, based on 100 parts by mass of the resin (A), so that the resulting resist exhibits high sensitivity. If the content of the nitrogen-containing compound (C) exceeds 10 parts by mass, the resulting resist may exhibit significantly low sensitivity. If the content of the nitrogen-containing compound (C) is less than 0.001 parts by mass, the pattern shape or the dimensional accuracy of the resulting resist may deteriorate depending on the process conditions.

### Additive (D)

The radiation-sensitive resin composition according to one embodiment of the invention may optionally include the additive (D) such as a fluorine-containing resin additive (d1), an alicyclic skeleton-containing additive (d2), a surfactant (d3), and a photosensitizer (d4). The content of each additive may be appropriately determined depending on the objective.

The fluorine-containing resin additive (d1) provides the surface of the resist film with water repellency during liquid immersion lithography. The fluorine-containing resin (C) thus suppresses elution of components from the resist film into an immersion liquid, and makes it possible to implement liquid immersion lithography by a high-speed scan without causing droplets to remain. Therefore, defects (e.g., watermark defects) that may occur due to liquid immersion lithography can be suppressed. The structure of the fluorine-containing resin additive (d1) is not particularly limited insofar as the fluorine-containing resin additive (d1) includes one or more fluorine atoms, and may be any of fluorine-containing resin additives (d1-1) to (d1-4) given below ((1) to (4)).

(1) Fluorine-containing resin additive (d1-1) that is not dissolved in a developer, but becomes alkali-soluble due to an acid
(2) Fluorine-containing resin additive (d1-2) that is dissolved in a developer, and exhibits increased alkali-solubility due to an acid
(3) Fluorine-containing resin additive (d1-3) that is not dissolved in a developer, but becomes alkali-soluble due to an alkali
(4) Fluorine-containing resin additive (d1-4) that is dissolved in a developer, and exhibits increased alkali-solubility due to an alkali

The fluorine-containing resin additive (d1) preferably includes at least one repeating unit selected from the repeating unit (A5) and the following fluorine-containing repeating units, and more preferably further includes at least one repeating unit selected from the group consisting of the repeating units (A1) to (A3), (A4), (A7), and (A8), and the additional repeating unit.

Examples of the fluorine-containing repeating unit include trifluoromethyl (meth)acrylate, 2,2,2-trifluoroethyl (meth)acrylate, perfluoroethyl (meth)acrylate, perfluoro-n-propyl (meth)acrylate, perfluoro-1-propyl (meth)acrylate, perfluoro-n-butyl (meth)acrylate, perfluoro-1-butyl (meth)acrylate, perfluoro-t-butyl (meth)acrylate, perfluorocyclohexyl (meth)acrylate, 2-(1,1,1,3,3,3-hexafluoro)propyl (meth)acrylate, 1-(2,2,3,3,4,4,5,5-octafluoro)pentyl (meth)acrylate, 1-(2,2,3,3,4,4,5,5-octafluoro)hexyl (meth)acrylate, perfluorocyclohexylmethyl (meth)acrylate, 1-(2,2,3,3,3-pentafluoro)propyl (meth)acrylate, 1-(2,2,3,3,4,4,4-heptafluoro)pentyl (meth)acrylate, 1-(3,3,4,4,5,5,6,6,7,7,8,8,9,9,10,10,10-heptadecafluoro)decyl (meth)acrylate, 1-(5-trifluoromethyl-3,3,4,4,5,6,6,6-octafluoro)hexyl (meth)acrylate, and the like.

Examples of a preferable fluorine-containing resin additive (d1) include polymers including a repeating unit shown by any of the following formulas (15-1) to (15-6). In the formulas (15-1) to (15-6), R²⁹ represents a hydrogen atom, a methyl group, or a trifluoromethyl group.

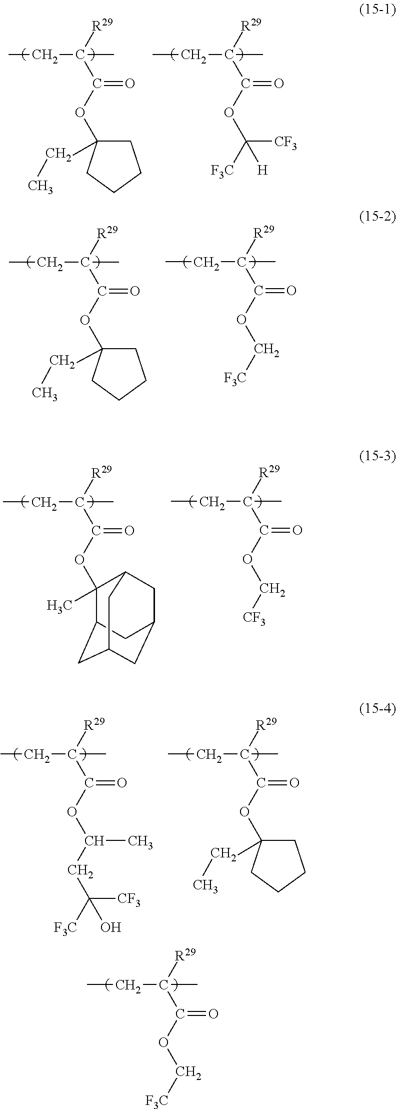

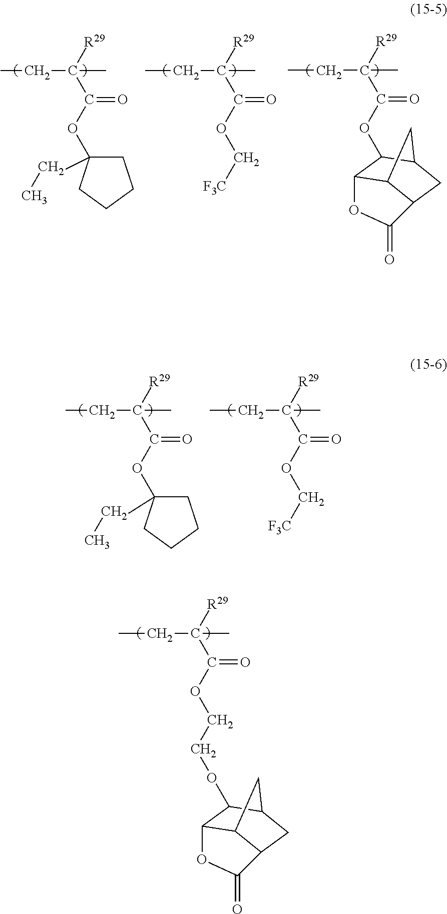

The alicyclic skeleton-containing additive (d2) used as the additive (D) is a component that further improves the dry etching resistance, the pattern shape, adhesion to a substrate, and the like.

Examples of the alicyclic skeleton-containing additive (d2) include adamantane derivatives such as 1-adamantanecarboxylic acid, 2-adamantanone, t-butyl-1-adamantanecarboxylate, t-butoxycarbonylmethyl 1-adamantanecarboxylate, α-butyrolactone 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, and 2,5-dimethyl-2,5-di(adamantylcarbonyloxy)hexane; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; alkyl carboxylates such as dimethyl adipate, diethyl adipate, dipropyl adipate, di-n-butyl adipate, and di-t-butyl adipate; 3-[2-hydroxy-2,2-bis(trifluoromethyl)ethyl]tetracyclo[4.4.0.1^{2,5}.1^{7,10}]dodecane, 2-hydroxy-9-methoxycarbonyl-5-oxo-4-oxa-tricyclo[4.2.1.0^{3,7}]nonane, and the like. These alicyclic skeleton-containing additives (d2) may be used either individually or in combination.

The surfactant (d3) used as the additive (D) improves the applicability, striation, developability, and the like.

Examples of the surfactant (d3) include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate, KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), MEGAFAC F171 and MEGAFAC F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.), and the like. These surfactants may be used either individually or in combination.

The sensitizer (d4) used as the additive (D) absorbs the energy of radiation, and transmits the energy to the acid generator (B), so that the amount of acid generated increases. The sensitizer (d4) improves the apparent sensitivity of the radiation-sensitive resin composition.

Examples of the sensitizer (d4) include carbazoles, acetophenones, benzophenones, naphthalenes, phenols, biacetyl, eosine, rose bengal, pyrenes, anthracenes, phenothiazines, and the like. These sensitizers (d4) may be used either individually or in combination.

At least one additive selected from the group consisting of a dye, a pigment, and an adhesion improver may also be used as the additive (D). A dye or a pigment visualizes the latent image in the exposed area, and reduces the effect of halation during exposure. An adhesion improver improves adhesion to a substrate. Examples of other additives include an alkali-soluble resin, a low-molecular-weight alkali solubility controller that includes an acid-dissociable protecting group, a halation inhibitor, a preservation stabilizer, an antifoaming agent, and the like.

These additives (D) may optionally be used either individually or in combination.

### Solvent (E)

An arbitrary solvent that dissolves the resin (A) and the photoacid generator (B) may be used as the solvent (E). When the radiation-sensitive resin composition further includes the nitrogen-containing compound (C) and the additive (D), it is preferable to use a solvent that also dissolves the nitrogen-containing compound (C) and the additive (D).

Examples of the solvent (E) include propylene glycol monoalkyl ether acetates such as propylene glycol monomethyl ether acetate, propylene glycol monoethyl ether acetate, propylene glycol mono-n-propyl ether acetate, propylene glycol mono-1-propyl ether acetate, propylene glycol mono-n-butyl ether acetate, propylene glycol mono-1-butyl ether acetate, propylene glycol mono-sec-butyl ether acetate, and propylene glycol mono-t-butyl ether acetate; cyclic ketones such as cyclopentanone, 3-methylcyclopentanone, cyclohexanone, 2-methylcyclohexanone, 2,6-dimethylcyclohexanone, and isophorone; linear or branched ketones such as 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone; alkyl 2-hydroxypropionates such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; alkyl 3-alkoxypropionates such as methyl 3-methoxypropionate, ethyl 3-methoxypropionate, methyl 3-ethoxypropionate, and ethyl 3-ethoxypropionate; n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, ethyl 2-hydroxy-2-methyl propionate, ethoxyethyl acetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and the like.

Among these, propylene glycol monoalkyl ether acetates (particularly propylene glycol monomethyl ether acetate) are preferable. Cyclic ketones, linear or branched ketones, alkyl 2-hydroxypropionates, alkyl 3-alkoxypropionate, γ-butyrolactone, and the like are also preferable. These solvents may be used either individually or in combination.

### Formation of Photoresist Pattern

The radiation-sensitive resin composition according to one embodiment of the invention is useful as a chemically-amplified resist. When using the radiation-sensitive resin composition as a chemically-amplified resist, the acid-dissociable group included in the resin component (mainly the resin (A)) dissociates due to an acid generated by the acid generator upon exposure so that a carboxyl group is produced. As a result, the solubility of the exposed area of the resist in an alkaline developer increases. Accordingly, the exposed area is dissolved (removed) in an alkaline developer to obtain a positive-tone photoresist pattern.

A photoresist pattern-forming method that uses the radiation-sensitive resin composition according to one embodiment of the invention includes (1) forming a photoresist film on a substrate using the radiation-sensitive resin composition (hereinafter may be referred to as “step (1)”), (2) exposing the photoresist film via a mask having a given pattern optionally via an immersion medium (hereinafter may be referred to as “step (2)”), and (3) developing the exposed photoresist film to form a photoresist pattern (hereinafter may be referred to as “step (3)”).

When performing liquid immersion lithography, the photoresist pattern-forming method may optionally include forming a protective film that is insoluble in an immersion liquid on the resist film before the step (2) in order to prevent the immersion liquid from coming in direct contact with the resist film. Examples of the protective film include a solvent removal-type protective film that is removed using a solvent before the step (3) (see Japanese Patent Application Publication (KOKAI) No. 2006-227632, for example), a developer removal-type protective film that is removed during development in the step (3) (see WO2005-069076 and WO2006-035790, for example), and the like. It is preferable to use the developer removal-type protective film from the viewpoint of throughput and the like.

In the step (1), a resin composition solution prepared by dissolving the above radiation-sensitive resin composition in a solvent is applied to a substrate (e.g., silicon wafer or silicon dioxide-coated wafer) by an appropriate application method (e.g., rotational coating, cast coating, or roll coating) to form a photoresist film. Specifically, the radiation-sensitive resin composition solution is applied so that the resulting resist film has a given thickness, and prebaked (PB) to volatilize the solvent from the film to obtain a resist film.

The thickness of the resist film is not particularly limited, but is preferably 50 to 3000 nm, and more preferably 50 to 1000 nm.

The prebaking temperature is determined depending on the composition of the radiation-sensitive resin composition, but is preferably about 30 to 200° C., and more preferably 50 to 150° C.

In the photoresist pattern-forming method using the radiation-sensitive resin composition according to one embodiment of the invention, an organic or inorganic antireflective film may be formed on the substrate (see Japanese Patent Publication (KOKOKU) No. 6-12452 (Japanese Patent Application Publication (KOKAI) No. 59-93448), for example) in order to maximize the potential of the radiation-sensitive resin composition. A protective film may be formed on the photoresist film (see Japanese Patent Application Publication (KOKAI) No. 5-188598, for example) in order to prevent an adverse effect of basic impurities and the like contained in the environmental atmosphere. The immersion liquid protective film may also be formed on the photoresist film. These methods may be used in combination.

In the step (2), radiation is applied to the photoresist film obtained by the step (1) optionally via an immersion medium (immersion liquid) (e.g., water). In this case, radiation is applied to the photoresist film via a mask having a given pattern.

As radiation used for liquid immersion lithography, visible rays, ultraviolet rays, deep ultraviolet rays, X-rays, electron beams, or the like are appropriately selected depending on the type of acid generator. It is preferable to use ArF excimer laser light (wavelength: 193 nm) or KrF excimer laser light (wavelength: 248 nm). It is particularly preferable use ArF excimer laser light (wavelength: 193 nm).

The exposure conditions (e.g., dose) are appropriately selected depending on the composition of the radiation-sensitive resin composition, the type of additive, and the like. In the photoresist pattern-forming method using the radiation-sensitive resin composition according to one embodiment of the invention, it is preferable to perform post-exposure bake (PEB) after exposure. The acid-dissociable group included in the resin component smoothly dissociates due to PEB. The PEB temperature is determined depending on the composition of the radiation-sensitive resin composition, but is preferably 30 to 200° C., and more preferably 50 to 170° C.

In the step (3), the exposed photoresist film is developed to form a given photoresist pattern. It is preferable to use an alkaline aqueous solution prepared by dissolving at least one alkaline compound (e.g., sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water as a developer. The concentration of the alkaline aqueous solution is preferably 10 mass % or less. If the concentration of the alkaline aqueous solution exceeds 10 mass %, the unexposed area may also be dissolved in the developer.

An organic solvent may be added to the alkaline aqueous solution (developer). Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methyl alcohol, ethyl alcohol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide, and the like. These organic solvents may be used either individually or in combination.

The organic solvent is preferably used in an amount of 100 parts by volume or less based on 100 parts by volume of the alkaline aqueous solution. If the amount of the organic solvent exceeds 100 parts by volume, the exposed area may remain undeveloped due to a decrease in developability.

An appropriate amount of a surfactant and the like may also be added to the alkaline aqueous solution (developer). After development using the alkaline aqueous solution (developer), the resist film is normally washed with water, and dried.

### EXAMPLES

The invention is further described below by way of examples. Note that the invention is not limited to the following examples. In the examples and comparative examples, the unit “parts” refers to “parts by mass”, and the unit “%” refers to “mass %” unless otherwise indicated. The following property value measuring methods and property evaluation methods were used.

### Mw, Mn, and Mw/Mn

The Mw and the Mn of each resin were measured by gel permeation chromatography (GPC) using GPC columns manufactured by Tosoh Corp. (G2000HXL×2, G3000HXL×1, G4000HXL×1) (flow rate: 1.0 ml/min, eluant: tetrahydrofuran, column temperature: 40° C., standard: monodisperse polystyrene). The dispersity “Mw/Mn” was calculated from the Mw and Mn measurement results.

### ¹³C-NMR Analysis

Each polymer was subjected to ¹³C-NMR analysis using a system “JNM-EX270” (manufactured by JEOL Ltd.).

### Low-Molecular-Weight Component Residual Rate

The low-molecular-weight component residual rate was determined by high-performance liquid chromatography (HPLC) using an Intersil ODS-25 μm column (4.6 mm (diameter)×250 mm) (manufactured by GL Sciences Inc.) (flow rate: 1.0 ml/min, eluant: acrylonitrile/0.1% phosphoric acid aqueous solution). Note that the term “low-molecular-weight component” refers to a component (mainly monomer) having a molecular weight of less than 1000 (preferably a component having a molecular weight equal to or lower than that of a trimer).

### Sensitivity (1)

A lower-layer antireflective film having a thickness of 77 nm (“ARC29A” manufactured by Brewer Science, Inc.) was formed on the surface of an 8-inch silicon wafer using a coater/developer “CLEAN TRACK ACT8” (manufactured by Tokyo Electron, Ltd.) to obtain a substrate.

The radiation-sensitive resin composition prepared in each example and comparative example was spin-coated onto the substrate using the coater/developer “CLEAN TRACK ACT8”, and prebaked (PB) under conditions shown in Table 3 to form a resist film having a thickness of 120 nm. The resist film was then exposed via a mask pattern using an ArF excimer laser exposure system (“NSR S306C” manufactured by Nikon Corp., NA 0.78, a: 0.93/0.62). The resist film was then subjected to PEB under conditions shown in Table 3, developed at 23° C. for 30 seconds using a 2.38% tetramethylammonium hydroxide aqueous solution, washed with water, and dried to form a positive-tone resist pattern.

The dose (mJ/cm²) at which a resist pattern having a line width of 90 nm and a line-to-line distance of 90 nm (1:1 line-and-space) was formed was taken as the optimum dose. The optimum dose was evaluated as the sensitivity (“Sensitivity (1) (mJ/cm²)” in Table 4). The line width and the line-to-line distance were measured using a scanning electron microscope (“S-9380” manufactured by Hitachi High-Technologies Corporation).

### Resolution (1)

The minimum line width (nm) of the line-and-space resist pattern formed when evaluating the sensitivity (1) was evaluated as the resolution (“Resolution (1) (nm)” in Table 4). A small value indicates an excellent resolution.

### Cross-Sectional Pattern Shape (1)

The cross-sectional shape of the 90 nm line-and-space pattern of the resist film formed when evaluating the sensitivity (1) was observed using a scanning electron microscope (“S-4800” manufactured by Hitachi High-Technologies Corporation), and the line width Lb in an intermediate area of the resist pattern and the line width La at the top of the resist film were measured. A case where the value “La/Lb” was within the range of “0.9≦(La/Lb)≦1.1” was evaluated as “Good”, and a case where the value “La/Lb” was outside the range of “0.9≦(La/Lb)≦1.1” was evaluated as “Bad”.

### PEB Temperature Dependence

A 90 nm line-and-space pattern resolved at the optimum dose when evaluating sensitivity (1) was observed from the above using a scanning electron microscope (“S-9380” manufactured by Hitachi High-Technologies Corporation). The difference between the line width when PEB was performed under conditions shown in Table 3 and the line width at the optimum dose when changing the PEB temperature by ±2° C. was divided by the difference in temperature, and the resulting value was taken as the PEB temperature dependence (nm/° C.). A case where the PEB temperature dependence was less than 3 nm/° C. was evaluated as “Good”, and a case where the PEB temperature dependence was 3 nm/° C. or more was evaluated as “Bad”.

### LWR (Line Width Roughness)

The line width of a 90 nm line-and-space pattern resolved at the optimum dose was observed from above at arbitrary points using a scanning electron microscope (“S-9380” manufactured by Hitachi High-Technologies Corporation), and a variation 3σ (nm) in line width was evaluated.

### Minimum Pre-Collapse Dimension

When exposing a 90 nm line-and-space pattern at a dose higher than the optimum dose determined when evaluating the sensitivity (1), the line width of the resulting pattern decreases, so that the resist pattern collapses. The line width at the maximum dose at which the resist pattern does not collapse was defined as a minimum pre-collapse dimension (nm), and used as an index of the pattern collapse resistance. The minimum pre-collapse dimension (nm) was measured using a scanning electron microscope (“S-9380” manufactured by Hitachi High-Technologies Corporation).

### Blob Defect

An 8-inch silicon wafer was subjected to a hexamethyldisilazane (HMDS) treatment at 100° C. for 60 seconds using a coater/developer “CLEAN TRACK ACTS” (manufactured by Tokyo Electron, Ltd.). The radiation-sensitive resin composition prepared in each example and comparative example was spin-coated onto the 8-inch silicon wafer, and pre-baked (PB) under conditions shown in Table 3 to form a film having a thickness of 120 nm.

The resist film was exposed using an ArF excimer laser exposure system (“NSR S306C” manufactured by Nikon Corp., NA 0.78, a: 0.85) at the optimum exposure dose determined when evaluating the sensitivity (1) via frosted glass on which a mask pattern was not formed. The resist film was then subjected to PEB under conditions shown in Table 3, developed at 23° C. for 30 seconds using a 2.38 mass % tetramethylammonium hydroxide aqueous solution, washed with water, and dried to form a blob defect evaluation substrate.

The presence or absence of blob defects in the blob defect evaluation substrate was measured using a system “KLA2351” (manufactured by KLA-Tencor). A case where the number of blob defects was 200 or less was evaluated as “Good”, and a case where the number of blob defects was more than 200 was evaluated as “Bad”.

### Sensitivity (2)

A lower-layer antireflective film having a thickness of 77 nm (“ARC29A” manufactured by Brewer Science, Inc.) was formed on the surface of an 8-inch silicon wafer using a coater/developer “CLEAN TRACK ACT12” (manufactured by Tokyo Electron, Ltd.) to obtain a substrate.

The radiation-sensitive resin composition was spin-coated onto the substrate using the coater/developer “CLEAN TRACK ACT12”, and prebaked (PB) under conditions shown in Table 3 to form a resist film having a thickness of 100 nm. When using the radiation-sensitive resin composition prepared in Example 6 or 7, a material “NFC TCX041” (manufactured by JSR Corporation) was spin-coated onto the resist film using the coater/developer “CLEAN TRACK ACT12”, and baked at 90° C. for 60 seconds to form an immersion protective film. The resist film was then exposed via a mask pattern using an ArF excimer laser exposure system (“Nikon S610C” manufactured by Nikon Corp., NA: 1.30, σ0/σ1=0.795, CrossPole). Purified water was used as an immersion liquid provided between the upper surface of the resist and the lens of the liquid immersion lithography system. The resist film was then subjected to PEB under conditions shown in Table 3, developed at 23° C. for 60 seconds using a 2.38 mass % tetramethylammonium hydroxide aqueous solution, washed with water, and dried to form a positive-tone resist pattern.

The dose (mJ/cm²) at which a resist pattern having a line width of 48 nm and a line-to-line distance of 48 nm (1:1 line-and-space) was formed was taken as the optimum dose. The optimum dose was evaluated as the sensitivity (“Sensitivity (2) (mJ/cm²)” in Table 5). The line width and the line-to-line distance were measured using a scanning electron microscope (“CG-4000” manufactured by Hitachi High-Technologies Corporation).

### Resolution (2)

The minimum line width (nm) of the line-and-space resist pattern formed when evaluating the sensitivity (2) was evaluated as the resolution (“Resolution (2) (nm)” in Table 5). A small value indicates an excellent resolution.

### LWR (2)

The line width of a 48 nm line-and-space pattern resolved at the optimum dose was observed from above at arbitrary points using a scanning electron microscope (“CG-4000” manufactured by Hitachi High-Technologies Corporation), and a variation 3σ (nm) in line width was evaluated.

### Defects Due to Liquid Immersion Lithography

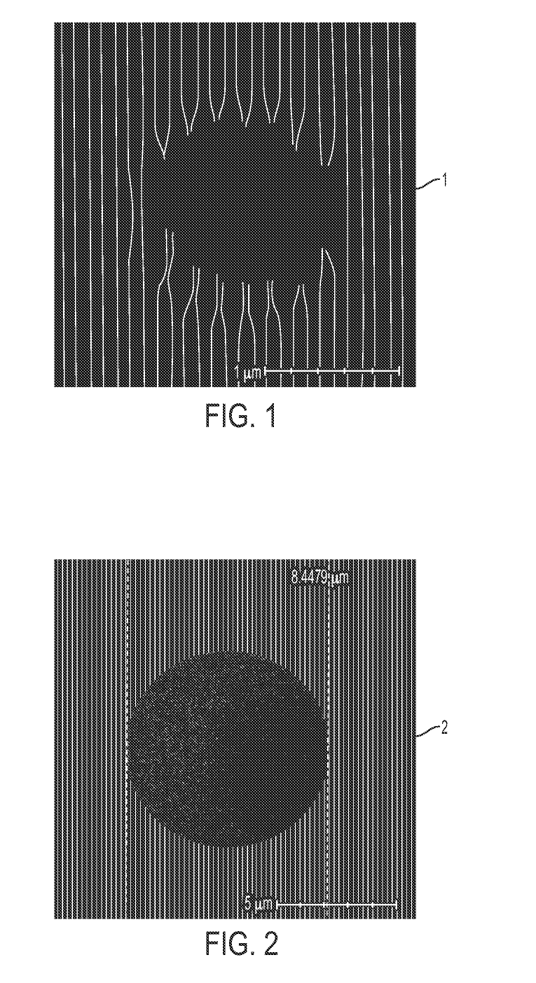

A 48 nm line-and-space pattern was formed at the dose determined when evaluating the sensitivity (2) using the method described in connection with the sensitivity (2) to form a liquid immersion lithography defect evaluation substrate. The evaluation substrate was subjected to measurement using a system “KLA2810” (manufactured by KLA-Tencor). The defects measured using the using a system “KLA2810” were observed using a scanning electron microscope “Vision G3” (manufactured by Applied Materials) to determine watermark defects and bubble defects due to liquid immersion lithography using an ArF excimer laser. These defects are evaluated as defects due to liquid immersion lithography. FIG. 1 shows a typical watermark defect 1 formed on the evaluation substrate, and FIG. 2 shows a typical bubble defect 2 formed on the evaluation substrate.

A case where the number of defects due to liquid immersion lithography was 200 or less was evaluated as “Good”, and a case where the number of defects due to liquid immersion lithography was more than 200 was evaluated as “Bad”.

The sensitivity, the resolution, and the LWR were evaluated by the evaluation methods described in the sections entitled “Sensitivity (1)”, “Resolution (1)”, and “LWR (1)” unless otherwise indicated.

In the examples and comparative examples, monomers (M-1) to (M-14) shown by the following formulas (M-1) to (M-4) were used to synthesize the polymer.

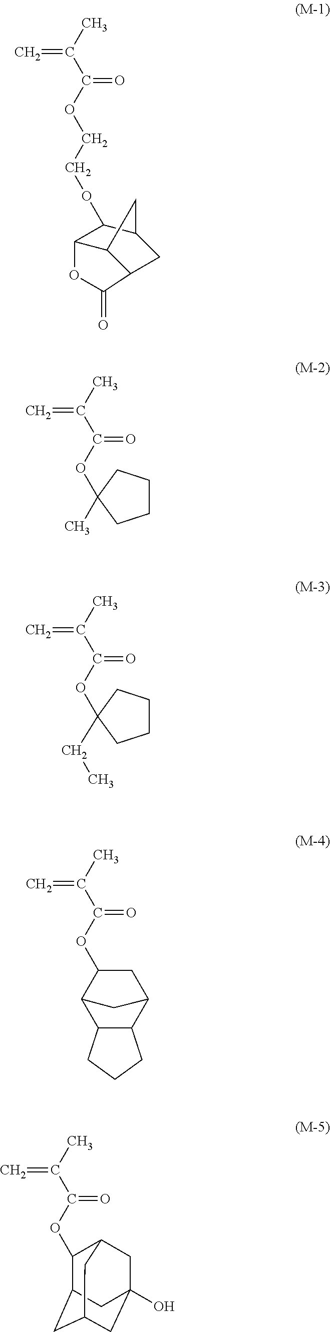

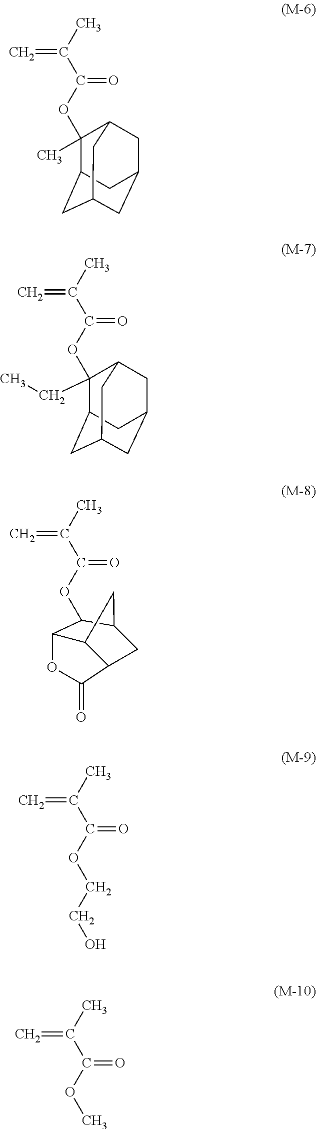

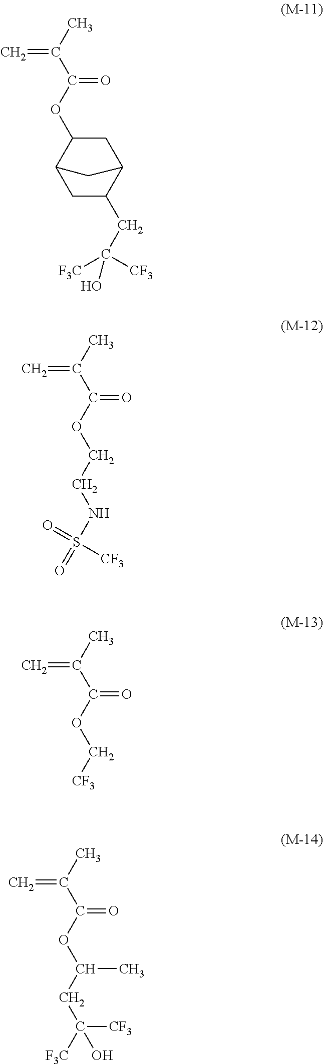

### Example 1

### Resin (A-I-1)

A monomer solution was prepared by dissolving 30.46 g (50 mol %) of the monomer (M-1) and 19.54 g (50 mol %) of the monomer (M-2) in 100 g of 2-butanone, and adding 1.91 g (5 mol %) of azobisisobutylonitrile (initiator) to the mixture.

A 500 ml three-necked flask equipped with a thermometer and a dropping funnel was charged with 50 g of 2-butanone, and purged with nitrogen for 30 minutes. The inside of the flask was then heated to 80° C. with stirring using a magnetic stirrer, and the monomer solution was added dropwise to the flask using the dropping funnel over 3 hours. The monomers were polymerized for 6 hours from the start of the addition of the monomer solution. After completion of polymerization, the polymer solution was cooled with water to 30° C. or less. The reaction mixture was then poured into 1000 g of methanol, and a precipitated white powder was collected by filtration. The white powder thus collected was washed twice with 200 g of methanol in a slurry state. The product was then collected by filtration, and dried at 50° C. for 17 hours to obtain a white powdery copolymer (36 g, yield: 72%). This copolymer is referred to as “resin (A-I-1)”.

The copolymer had an Mw of 6930 and an Mw/Mn ratio of 1.61. The ratio of repeating units derived from the monomers (M-1) and (M-2) determined by ¹³C-NMR analysis was 50.9:49.1 (mol %). The copolymer had a low-molecular-weight component residual rate of 0.04 mass %. The measurement results are shown in Table 2.

### Examples 2 to 7 and Comparative Example 1

### Resins (A-I-2) to (A-I-8)

Resins (A-I-2) to (A-I-8) were synthesized in the same manner as in Example 1, except for changing the composition as shown in Table 1. In Table 1, “AIBN” indicates azobisisobutyronitrile, and “MAIB” indicates dimethyl-2,2-azoisobutylate.

The measurement results for the ratio (mol %) of repeating units determined by ¹³C-NMR analysis, the yield (%), the Mw, the dispersity (Mw/Mn), and the low-molecular-weight component residual rate (mass %) of the resins (A-I-2) to (A-I-8) are shown in Table 2.

TABLE 1

| | | Monomer 1 | | Monomer 2 | | Monomer 3 | | Initiator | |
|---|---|---|---|---|---|---|---|---|---|
| | | | Amount | | Amount | | Amount | | Amount |
| | Resin | Type | (mol %) | Type | (mol %) | Type | (mol %) | Type | (mol %) |
| Example 1 | A-I-1 | M-1 | 50 | M-2 | 50 | — | — | AIBN | 5 |
| Example 2 | A-I-2 | M-1 | 50 | M-3 | 40 | M-4 | 10 | MAIB | 5 |
| Example 3 | A-I-3 | M-1 | 50 | M-2 | 40 | M-4 | 10 | MAIB | 5 |
| Example 4 | A-I-4 | M-1 | 50 | M-3 | 40 | M-5 | 10 | MAIB | 5 |
| Example 5 | A-I-5 | M-1 | 50 | M-3 | 15 | M-6 | 35 | MAIB | 5 |
| Example 6 | A-I-6 | M-1 | 50 | M-3 | 15 | M-6 | 35 | AIBN | 5 |
| Example 7 | A-I-7 | M-1 | 50 | M-2 | 35 | M-7 | 15 | AIBN | 5 |
| Comparative | A-I-8 | M-8 | 50 | M-5 | 15 | M-6 | 35 | MAIB | 5 |
| Example 1 | | | | | | | | | |

TABLE 2

| | | ¹³C-NMR results | | | | | | | Molecular | | Low-molecular-weight |
|---|---|---|---|---|---|---|---|---|---|---|---|
| | | Repeating unit A1 | | Repeating unit A2 | | Repeating unit A3 | | | weight | | component residual |
| | | | Amount | | Amount | | Amount | Yield | | Mw/ | rate |
| | Resin | Monomer | (mol %) | Monomer | (mol %) | Monomer | (mol %) | (%) | Mw | Mn | (mass %) |
| Example 1 | A-I-1 | M-1 | 50.9 | M-2 | 49.1 | — | — | 72 | 6930 | 1.61 | 0.04 |
| Example 2 | A-I-2 | M-1 | 50.3 | M-3 | 39.3 | M-4 | 10.4 | 76 | 7120 | 1.62 | 0.05 |
| Example 3 | A-I-3 | M-1 | 50.7 | M-2 | 39.8 | M-4 | 9.5 | 73 | 7180 | 1.63 | 0.04 |
| Example 4 | A-I-4 | M-1 | 50.6 | M-3 | 39.4 | M-5 | 10 | 70 | 7200 | 1.64 | 0.03 |
| Example 5 | A-I-5 | M-1 | 50.4 | M-4 | 15.1 | M-6 | 34.5 | 73 | 6720 | 1.60 | 0.04 |
| Example 6 | A-I-6 | M-1 | 50.9 | M-4 | 14.8 | M-6 | 34.3 | 72 | 6510 | 1.59 | 0.05 |
| Example 7 | A-I-7 | M-1 | 50.1 | M-2 | 35.2 | M-7 | 14.7 | 73 | 6380 | 1.59 | 0.04 |
| Comparative | A-I-8 | M-8 | 50.3 | M-5 | 14.9 | M-6 | 34.8 | 69 | 6790 | 1.62 | 0.05 |
| Example 1 | | | | | | | | | | | |

### Preparation of Radiation-Sensitive Resin Composition

Table 3 shows the composition of the radiation-sensitive resin composition prepared in each example and comparative example, and the PB and PEB conditions. Each component (photoacid generator (B), nitrogen-containing compound (C), additive (D), and solvent (E)) of the radiation-sensitive resin composition other than the resins (A-I-1) to (A-I-8) synthesized in each example and comparative example is given below.

### Photoacid Generator (B)

(B-1): 4-cyclohexylphenyldiphenylsulfonium nonafluoro-n-butanesulfonate
(B-2): triphenylsulfonium.nonafluoro-n-butanesulfonate
(B-3): 1-(4-n-butoxynaphthalen-1-yl)tetrahydrothiophenium nonafluoro-n-butanesulfonate
(B-4): 1-(4-n-butoxynaphthalen-1-yl)tetrahydrothiophenium 2-(bicyclo[2.2.1]heptan-2-yl)-1,1,2,2-tetrafluoroethanesulfonate
(B-5): triphenylsulfonium 2-(bicyclo[2.2.1]hept-2-yl)-1,1,2,2-tetrafluoroethanesulfonate
(B-6): triphenylsulfonium 2-(bicyclo[2.2.1]hept-2-yl)-1,1-difluoroethanesulfonate
(B-7): triphenylsulfonium 1,1,2,2-tetrafluoro-2-(norbornan-2-yl)ethanesulfonate

### Nitrogen-Containing Compound (C)

(C-1): N-t-butoxycarbonyl-4-hydroxypiperidine
(C-2): (R)-(+)-1-(t-butoxycarbonyl)-2-piperidinemethanol
(C-3): N-t-butoxycarbonylpyrrolidine
(C-4): N-t-butoxycarbonyl-2-phenylbenzimidazole

### Additive (D)

(D-1): t-butoxycarbonylmethyl lithocholate
(D-2): copolymer of 2,2,2-trifluoroethyl methacrylate and 1-ethylcyclohexyl methacrylate (mixing ratio of 2,2,2-trifluoroethyl methacrylate and 1-ethylcyclohexyl methacrylate: 30:70 (molar ratio), ratio of 2,2,2-trifluoroethyl methacrylate and 1-ethylcyclohexyl methacrylate in the copolymer: 29.5:70.5 (molar ratio), Mw: 7300, Mw/Mn: 1.60)
(D-3): 4-[2-hydroxy-2,2-bis(trifluoromethyl)ethyl]tetracyclo[6.2.1.1^{3,6}.0^{2,7}]dodecane

### Solvent (E)

(E-1): propylene glycol monomethyl ether acetate
(E-2): cyclohexanone
(E-3): γ-butyrolactone
(E-4): ethyl lactate

TABLE 3

| | | | | | Nitrogen- | | | | | | | | | |
|---|---|---|---|---|---|---|---|---|---|---|---|---|---|---|
| | | | Photoacid | | containing | | | | | | | | | |
| | Resin (A) | | generator (B) | | compound (C) | | Additive (D) | | Solvent (E) | | PB | | PEB | |
| | | Parts by | | Parts by | | Parts by | | Parts by | | Parts by | Temp. | Time | Temp. | Time |
| | Type | mass | Type | mass | Type | mass | Type | mass | Type | mass | (° C.) | (s) | (° C.) | (s) |
| Example 8 | A-I-1 | 100 | B-1 | 9.6 | C-1 | 1.05 | — | — | E-1 | 1400 | 110 | 60 | 105 | 60 |
| | | | | | | | | | E-2 | 600 | | | | |
| Example 9 | A-I-2 | 100 | B-2 | 1.5 | C-2 | 0.65 | — | — | E-1 | 1400 | 110 | 60 | 115 | 60 |
| | | | B-3 | 6.0 | | | | | E-2 | 600 | | | | |
| | | | | | | | | | E-3 | 30 | | | | |
| Example 10 | A-I-3 | 100 | B-4 | 2.0 | C-1 | 1.10 | — | — | E-1 | 1400 | 110 | 60 | 130 | 60 |
| | | | B-5 | 6.5 | | | | | E-2 | 600 | | | | |
| | | | | | | | | | E-3 | 30 | | | | |
| Example 11 | A-I-4 | 100 | B-4 | 2.0 | C-1 | 1.10 | — | — | E-1 | 1400 | 110 | 60 | 110 | 60 |
| | | | B-5 | 6.5 | | | | | E-2 | 600 | | | | |
| | | | | | | | | | E-3 | 30 | | | | |
| Example 12 | A-I-5 | 100 | B-4 | 4.0 | C-3 | 0.36 | D-1 | 40 | E-1 | 1400 | 110 | 60 | 115 | 60 |
| | | | B-6 | 1.0 | | | | | E-2 | 600 | | | | |
| Example 13 | A-I-6 | 100 | B-2 | 7.0 | C-1 | 1.12 | — | — | E-1 | 1400 | 110 | 60 | 115 | 60 |
| | | | B-3 | 2.0 | | | | | E-2 | 600 | | | | |
| | | | | | | | | | E-3 | 30 | | | | |
| Example 14 | A-I-7 | 100 | B-2 | 7.0 | C-1 | 1.53 | — | — | E-1 | 1400 | 110 | 60 | 100 | 60 |
| | | | B-3 | 2.0 | | | | | E-2 | 600 | | | | |
| | | | | | | | | | E-3 | 30 | | | | |
| Example 15 | A-I-6 | 100 | B-2 | 7.0 | C-1 | 1.12 | D-2 | 5.0 | E-1 | 1400 | 110 | 60 | 115 | 60 |
| | | | B-3 | 2.0 | | | | | E-2 | 600 | | | | |
| | | | | | | | | | E-3 | 30 | | | | |
| Example 16 | A-I-7 | 100 | B-2 | 7.0 | C-1 | 1.53 | D-2 | 5.0 | E-1 | 1400 | 110 | 60 | 100 | 60 |
| | | | B-3 | 2.0 | | | | | E-2 | 600 | | | | |
| | | | | | | | | | E-3 | 30 | | | | |
| Comparative | A-I-8 | 100 | B-2 | 1.0 | C-4 | 0.42 | — | — | E-1 | 2000 | 130 | 60 | 130 | 60 |
| Example 2 | | | B-3 | 4.0 | | | | | E-3 | 30 | | | | |

### Example 8

100 parts by mass of the resin (A-I-1) obtained in Example 1, 9.6 parts by mass of 4-cyclohexylphenyldiphenylsulfonium nonafluoro-n-butanesulfonate (B-1) (photoacid generator (B)), and 1.05 parts by mass of N-t-butoxycarbonyl-4-hydroxypiperidine (C-1) (nitrogen-containing compound (C)) were mixed. 1400 parts by mass of propylene glycol monomethyl ether acetate (E-1) and 600 parts by mass of cyclohexanone (E-2) (solvent (E)) were added to the mixture to obtain a mixed solution. The mixed solution was filtered through a filter having a pore size of 0.20 μm to prepare a radiation-sensitive resin composition. Table 3 shows the composition of the radiation-sensitive resin composition.

The sensitivity (1), the resolution (1), the cross-sectional pattern shape (1), the PEB temperature dependence, the LWR (line width roughness), the minimum pre-collapse dimension, and blob defects of the radiation-sensitive resin composition prepared in Example 8 were evaluated. The evaluation results are shown in Table 4.

TABLE 4

| | | | | | | Minimum | |
|---|---|---|---|---|---|---|---|
| | Sensitivity (1) | Resolution (1) | Cross-sectional | PEB temperature | | pre-collapse | |
| | (mJ/cm²) | (nm) | pattern shape (1) | dependence | LWR (nm) | dimension (nm) | Blob defect |
| Example 8 | 32.5 | 75 | Good | Good | 6.1 | 47 | Good |
| Example 9 | 31.5 | 80 | Good | Good | 6.0 | 45 | Good |
| Example 10 | 32.0 | 80 | Good | Good | 6.2 | 46 | Good |
| Example 11 | 33.5 | 80 | Good | Good | 6.1 | 45 | Good |
| Example 12 | 30.5 | 80 | Good | Good | 6.5 | 42 | Good |
| Example 13 | 35.0 | 75 | Good | Good | 6.7 | 38 | Good |
| Example 14 | 36.5 | 80 | Good | Good | 5.7 | 32 | Good |
| Example 15 | 34.0 | 80 | Good | Good | 6.5 | 38 | Good |
| Example 16 | 36.0 | 75 | Good | Good | 5.6 | 30 | Good |
| Comparative | 35.0 | 90 | Bad | Bad | 7.2 | 47 | Bad |
| Example 2 | | | | | | | |

### Examples 9 to 16 and Comparative Example 2

A radiation-sensitive resin composition (Examples 9 to 16 and Comparative Example 2) was obtained in the same manner as in Example 8, except for changing the components as shown in Table 3. The sensitivity (1), the resolution (1), the cross-sectional pattern shape (1), the PEB temperature dependence, the LWR (line width roughness), the minimum pre-collapse dimension, and blob defects of the radiation-sensitive resin compositions prepared in Examples 9 to 16 and Comparative Example 2 were evaluated. The evaluation results are shown in Table 4.

The sensitivity (2), the resolution (2), and the LWR (2) of the radiation-sensitive resin compositions prepared in Examples 13 to 16 were also evaluated. The evaluation results are shown in Table 5.

TABLE 5

| | Sensitivity (2) | | |
|---|---|---|---|
| Example | (mJ/cm²) | Resolution (2) (nm) | LWR (2) (nm) |
| 13 | 17.5 | 45 | 5.7 |
| 14 | 18.0 | 42 | 4.2 |
| 15 | 17.5 | 45 | 5.8 |
| 16 | 17.0 | 42 | 4.3 |

### Example 17

### Resin (A-II-1)

49.95 g (40 mol %) of the monomer (M-1), 32.03 g (40 mol %) of the monomer (M-3), and 6.20 g (10 mol %) of the monomer (M-4) were dissolved in 200 g of 2-butanone. 3.91 g of azobisisobutyronitrile was then added to the solution to prepare a monomer solution.

A 500 ml three-necked flask equipped with a dropping funnel was charged with 11 g (10 mol %) of the monomer (M-2) and 100 g of 2-butanone, and purged with nitrogen for 30 minutes. The inside of the flask was then heated to 80° C. with stirring using a magnetic stirrer, and the monomer solution was added dropwise to the flask using the dropping funnel over 3 hours. The monomers were polymerized for 6 hours from the start of the addition of the monomer solution.

After completion of polymerization, the polymer solution was cooled with water to 30° C. or less. The polymer solution was then added to 2000 g of methanol, and a precipitated white powder was collected by filtration. The white powder collected by filtration was washed twice with 800 g of methanol in a slurry state, collected by filtration, and dried at 60° C. for 17 hours to obtain a white powdery copolymer (68 g, yield: 68%). This copolymer is referred to as “resin (A-II-1)”.

The copolymer had an Mw of 6620 and an Mw/Mn ratio of 1.61. The ratio of repeating units derived from the monomers (M-1), (M-4), (M-2), and (M-3) determined by ¹³C-NMR analysis was 40.2:10.1:9.7:40.0 (mol %). The copolymer had a low-molecular-weight component residual rate of 0.04 mass %. The measurement results are shown in Table 7.

### Example 18 and Comparative Examples 3 and 4

### Resins (A-II-2) to (A-II-4)

Resins (A-II-2) to (A-II-4) were synthesized in the same manner as in Example 17, except for changing the composition as shown in Table 6.

The measurement results for the ratio (mol %) of repeating units determined by ¹³C-NMR analysis, the yield (%), the Mw, the dispersity (Mw/Mn), and the low-molecular-weight component residual rate (mass %) of the resins (A-II-2) to (A-II-4) are shown in Table 7.

TABLE 6

| | | Monomer 1 | | Monomer 2 | | Monomer 3-1 | | Monomer 3-2 | |
|---|---|---|---|---|---|---|---|---|---|
| | | | Amount | | Amount | | Amount | | Amount |
| | Resin | Type | (mol %) | Type | (mol %) | Type | (mol %) | Type | (mol %) |
| Example 17 | A-II-1 | M-1 | 40 | M-4 | 10 | M-2 | 10 | M-3 | 40 |
| Example 18 | A-II-2 | M-1 | 40 | M-5 | 10 | M-2 | 10 | M-3 | 40 |
| Comparative | A-II-3 | M-6 | 40 | M-4 | 10 | M-2 | 10 | M-3 | 40 |
| Example 3 | | | | | | | | | |
| Comparative | A-II-4 | M-6 | 40 | M-5 | 10 | M-2 | 10 | M-3 | 40 |
| Example 4 | | | | | | | | | |

TABLE 7

| | | | | | | | | | | | | | Low-molecular- |
|---|---|---|---|---|---|---|---|---|---|---|---|---|---|
| | | ¹³C-NMR results | | | | | | | | | Molecular | | weight |
| | | Repeating unit 1 | | Repeating unit 2 | | Repeating unit 3-1 | | Repeating unit 3-2 | | | weight | | component |
| | | | Amount | | Amount | | Amount | | Amount | Yield | | Mw/ | residual rate |
| | Resin | Monomer | (mol %) | Monomer | (mol %) | Monomer | (mol %) | Monomer | (mol %) | (%) | Mw | Mn | (mass %) |
| Example 17 | A-II-1 | M-1 | 40.2 | M-4 | 10.1 | M-2 | 9.7 | M-3 | 40.0 | 68 | 6620 | 1.51 | 0.04 |
| Example 18 | A-II-2 | M-1 | 40.3 | M-5 | 9.9 | M-2 | 9.8 | M-3 | 40.0 | 70 | 7180 | 1.59 | 0.03 |
| Comparative | A-II-3 | M-6 | 41.3 | M-4 | 10.0 | M-2 | 9.2 | M-3 | 39.5 | 66 | 6800 | 1.35 | 0.03 |
| Example 3 | | | | | | | | | | | | | |
| Comparative | A-II-4 | M-6 | 41.9 | M-5 | 8.0 | M-2 | 9.9 | M-3 | 40.2 | 72 | 6800 | 1.40 | 0.04 |
| Example 4 | | | | | | | | | | | | | |

### Example 19

100 parts by mass of the resin (A-II-1) obtained in Example 17, 7.0 parts by mass of triphenylsulfonium nonafluoro-n-butanesulfonate (B-1) (photoacid generator (B)), 2.0 parts by mass of 1-(4-n-butoxynaphthyl)tetrahydrothiophenium nonafluoro-n-butanesulfonate (B-3) (photoacid generator (B)), and 1.53 parts by mass of N-t-butoxycarbonyl-4-hydroxypiperidine (C-1) (nitrogen-containing compound (C)) were mixed. 1540 parts by mass of propylene glycol monomethyl ether acetate (E-1), 660 parts by mass of cyclohexanone (E-2), and 30 parts by mass of γ-butyrolactone (E-3) (solvent (D)) were added to the mixture to obtain a mixed solution. The mixed solution was filtered through a filter having a pore size of 200 nm to obtain a radiation-sensitive resin composition. The composition of the radiation-sensitive resin composition is shown in Table 8.

The sensitivity, the resolution, the cross-sectional pattern shape, the LWR (line width roughness), the minimum pre-collapse dimension, and blob defects of the radiation-sensitive resin composition prepared in Example 19 were evaluated. The evaluation results are shown in Table 9.

### Example 20 and Comparative Examples 5 and 6

A radiation-sensitive resin composition (Example 20 and Comparative Examples 5 and 6) was obtained in the same manner as in Example 19, except for changing the components as shown in Table 8. The sensitivity, the resolution, the cross-sectional pattern shape, the LWR (line width roughness), the minimum pre-collapse dimension, and blob defects of the radiation-sensitive resin compositions prepared in Example 20 and Comparative Examples 5 and 6 were evaluated. The evaluation results are shown in Table 9.

TABLE 8

| | | | | | Nitrogen- | | | | | | | |
|---|---|---|---|---|---|---|---|---|---|---|---|---|
| | | | Photoacid | | containing | | | | | | | |
| | | | generator | | compound | | | | | | | |
| | Resin (A) | | (B) | | (C) | | Solvent (E) | | | | | |
| | | Parts by | | Parts by | | Parts by | | Parts by | PB | | PEB | |
| | Type | mass | Type | mass | Type | mass | Type | mass | Temp. | Time | Temp. | Time |
| Example 19 | A-II-1 | 100 | B-2 | 7.0 | C-1 | 1.53 | E-1 | 1540 | 110 | 60 | 100 | 60 |
| | | | B-3 | 2.0 | | | E-2 | 660 | | | | |
| | | | | | | | E-3 | 30 | | | | |
| Example 20 | A-II-2 | 100 | B-2 | 7.0 | C-1 | 1.53 | E-1 | 1540 | 110 | 60 | 100 | 60 |
| | | | B-3 | 2.0 | | | E-2 | 660 | | | | |
| | | | | | | | E-3 | 30 | | | | |
| Comparative | A-II-3 | 100 | B-2 | 7.0 | C-1 | 1.53 | E-1 | 1540 | 110 | 60 | 100 | 60 |
| Example 5 | | | B-3 | 2.0 | | | E-2 | 660 | | | | |
| | | | | | | | E-3 | 30 | | | | |
| Comparative | A-II-4 | 100 | B-2 | 7.0 | C-1 | 1.53 | E-1 | 1540 | 110 | 60 | 100 | 60 |
| Example 6 | | | B-3 | 2.0 | | | E-2 | 660 | | | | |
| | | | | | | | E-3 | 30 | | | | |

TABLE 9

| | | | | | Minimum | |
|---|---|---|---|---|---|---|
| | | | Cross- | | pre- | |
| | | Reso- | sectional | | collapse | |
| | Sensitivity | lution | pattern | LWR | dimension | Blob |
| | (mJ/cm²) | (nm) | shape | (nm) | (nm) | defect |
| Example 19 | 53.5 | 65 | Good | 7.0 | 41 | Good |
| Example 20 | 55.0 | 70 | Good | 7.2 | 40 | Good |
| Comparative | 57.0 | 75 | Good | 7.8 | 44 | Good |
| Example 5 | | | | | | |
| Comparative | 56.0 | 75 | Good | 7.9 | 46 | Good |
| Example 6 | | | | | | |

### Example 21

### Resin (A-III-1)

40.66 g (40 mol %) of the monomer (M-1), 24.72 g (15 mol %) of the monomer (M-11), and 34.62 g (45 mol %) of the monomer (M-6) were dissolved in 200 g of 2-butanone. 5.27 g of dimethyl azobisisobutyronitrile was then added to the solution to prepare a monomer solution.

A 500 ml three-necked flask equipped with a dropping funnel was charged with 100 g of 2-butanone, and purged with nitrogen for 30 minutes. The inside of the flask was then heated to 80° C. with stirring using a magnetic stirrer, and the monomer solution was added dropwise to the flask at a rate of 1.9 ml/min. The monomers were polymerized for 6 hours from the start of the addition of the monomer solution.

After completion of polymerization, the polymer solution was cooled with water to 30° C. or less. The polymer solution was then added to 1500 g of n-heptane, and a precipitated white powder was collected by filtration. The white powder thus collected was washed twice with 300 g of n-heptane. The product was then collected by filtration, and dried at 50° C. for 17 hours to obtain a white powdery copolymer (77 g, yield: 77%). This copolymer is referred to as “resin (A-III-1)”.

The copolymer had an Mw of 7310 and an Mw/Mn ratio of 1.69. The ratio of repeating units derived from the monomers (M-1), (M-11), and (M-6) determined by ¹³C-NMR analysis was 40.3:15.1:44.6 (mol %). The copolymer had a low-molecular-weight component residual rate of 0.04 mass %. The measurement results are shown in Table 11.

### Example 22 and Comparative Examples 7 and 8

### Resins (A-III-2) to (A-III-4)

Resins (A-III-2) to (A-III-4) were synthesized in the same manner as in Example 21, except for changing the composition as shown in Table 10.

The measurement results for the ratio (mol %) of repeating units determined by ¹³C-NMR analysis, the yield (%), the Mw, the dispersity (Mw/Mn), and the low-molecular-weight component residual rate (mass %) of the resins (A-III-2) to (A-III-4) are shown in Table 11.

TABLE 10

| | | Monomer 1 | | Monomer 2 | | Monomer 3 | |
|---|---|---|---|---|---|---|---|
| | | | Amount | | Amount | | Amount |
| | Resin | Type | (mol %) | Type | (mol %) | Type | (mol %) |
| Example 21 | A-III-1 | M-1 | 40 | M-11 | 15 | M-6 | 45 |
| Example 22 | A-III-2 | M-1 | 40 | M-11 | 15 | M-2 | 45 |
| Comparative | A-III-3 | M-8 | 40 | M-11 | 15 | M-6 | 45 |
| Example 7 | | | | | | | |
| Comparative | A-III-4 | M-8 | 40 | M-11 | 15 | M-2 | 45 |
| Example 8 | | | | | | | |

TABLE 11

| | | | | | | | | | | | Low-molecular- |
|---|---|---|---|---|---|---|---|---|---|---|---|
| | | ¹³C-NMR results | | | | | | | Molecular | | weight |
| | | Repeating unit 1 | | Repeating unit 2 | | Repeating unit 3-1 | | | weight | | component |
| | | | Amount | | Amount | | Amount | Yield | | Mw/ | residual rate |
| | Resin | Monomer | (mol %) | Monomer | (mol %) | Monomer | (mol %) | (%) | Mw | Mn | (mass %) |
| Example 21 | A-III-1 | M-1 | 40.3 | M-11 | 15.1 | M-6 | 44.6 | 77 | 7310 | 1.69 | 0.04 |
| Example 22 | A-III-2 | M-1 | 40.2 | M-11 | 15.0 | M-2 | 44.8 | 73 | 7020 | 1.68 | 0.04 |
| Comparative | A-III-3 | M-8 | 40.4 | M-11 | 15.0 | M-6 | 44.6 | 83 | 7290 | 1.55 | 0.05 |
| Example 7 | | | | | | | | | | | |
| Comparative | A-III-4 | M-8 | 40.1 | M-11 | 14.6 | M-2 | 45.3 | 81 | 6920 | 1.61 | 0.06 |
| Example 8 | | | | | | | | | | | |

### Example 23

10 parts by mass of the resin (A-III-1) obtained in Example 21, 90 parts by mass of the resin (A-III-2) obtained in Example 22, 4.0 parts by mass of 1-(4-n-butoxynaphthylen-1yl)tetrahydrothiophenium nonafluoro-n-butanesulfonate (B-3) (photoacid generator (B)), 1.0 parts by mass of triphenylsulfonium nonafluoro-n-butanesulfonate (B-2) (photoacid generator (B)), 2.0 parts by mass of 1-(4-n-butoxynaphthalen-1-yl)tetrahydrothiophenium 2-(bicyclo[2.2.1]heptan-2-yl)-1,1,2,2-tetrafluoroethanesulfonate (B-4) (photoacid generator (B)), 0.72 parts by mass of N-t-butoxycarbonyl-2-phenylbenzimidazole (C-1) (nitrogen-containing compound (C)), and 0.02 parts by mass of 4-[2-hydroxy-2,2-bis(trifluoromethyl)ethyl]tetracyclo[6.2.1.1^{3,6}.0^{2,7}]dodecane (D-3) (additive (D)) were mixed. 1090 parts by mass of propylene glycol monomethyl ether acetate (E-1) (solvent (D)) was added to the mixture to obtain a mixed solution. The mixed solution was filtered through a filter having a pore size of 200 nm to obtain a radiation-sensitive resin composition. The composition of the radiation-sensitive resin composition is shown in Table 12.

The sensitivity, the resolution, the cross-sectional pattern shape, the LWR (line width roughness), the minimum pre-collapse dimension, and blob defects of the radiation-sensitive resin composition prepared in Example 23 were evaluated. The evaluation results are shown in Table 13.

### Comparative Example 9

A radiation-sensitive resin composition (Comparative Example 9) was obtained in the same manner as in Example 23, except for changing the components as shown in Table 12. The sensitivity, the resolution, the cross-sectional pattern shape, the LWR (line width roughness), the minimum pre-collapse dimension, and blob defects of the radiation-sensitive resin composition prepared in Comparative Example 9 were evaluated. The evaluation results are shown in Table 13.

TABLE 12

| | | | | | Nitrogen- | | | | | | | | | |
|---|---|---|---|---|---|---|---|---|---|---|---|---|---|---|
| | | | Photoacid | | containing | | | | | | | | | |
| | | | generator | | compound | | Additive | | | | | | | |
| | Resin (A) | | (B) | | (C) | | (D) | | Solvent (E) | | | | | |
| | | Parts by | | Parts by | | Parts by | | Parts by | | Parts by | PB | | PEB | |
| | Type | mass | Type | mass | Type | mass | Type | mass | Type | mass | Temp. | Time | Temp. | Time |
| Example 23 | A-III-1 | 10 | B-3 | 4.0 | C-1 | 0.72 | D-3 | 0.02 | E-1 | 1090 | 110 | 60 | 120 | 60 |
| | A-III-2 | 90 | B-2 | 1.0 | | | | | | | | | | |
| | | | B-4 | 2.0 | | | | | | | | | | |
| Comparative | A-III-3 | 10 | B-3 | 4.0 | C-2 | 0.72 | D-3 | 0.02 | E-1 | 1090 | 110 | 60 | 120 | 60 |
| Example 9 | A-III-4 | 90 | B-2 | 1.0 | | | | | | | | | | |
| | | | B-4 | 2.0 | | | | | | | | | | |

TABLE 13

| | | | | | Minimum | |
|---|---|---|---|---|---|---|
| | | | Cross- | | pre- | |
| | | Reso- | sectional | | collapse | |
| | Sensitivity | lution | pattern | LWR | dimension | Blob |
| | (mJ/cm²) | (nm) | shape | (nm) | (nm) | defect |
| Example 23 | 32.5 | 80 | Good | 6.1 | 44 | Good |
| Comparative | 33.5 | 90 | Bad | 7.2 | 47 | Bad |
| Example 9 | | | | | | |

### Example 24

### Resin (A-IV-1)

42.04 g (40 mol %) of the monomer (M-1), 42.26 g (45 mol %) of the monomer (M-6), and 15.70 g (15 mol %) of the monomer (M-12) were dissolved in 200 g of 2-butanone. 4.61 g of dimethyl azobisisobutyrate was added to the solution to prepare a monomer solution. The monomer solution was put in a dropping funnel. A 500 ml three-necked flask charged with 100 g of 2-butanone was purged with nitrogen for 30 minutes. The inside of the flask was then heated to 80° C. with stirring, and the monomer solution was added dropwise to the flask from the dropping funnel at a rate of 1.9 ml/min. The monomers were polymerized for 6 hours from the start of the addition of the monomer solution. After completion of polymerization, the reaction solution was cooled with water to 30° C. or less, and poured into 1500 g of n-heptane. A white powder was precipitated by this operation. The white powder was collected by filtration, and washed twice with 300 g of n-heptane in a slurry state. The white powder was then filtered, and dried at 60° C. for 17 hours under vacuum to obtain 76 g of a white powdery resin (A-IV-1). The yield was 76%.

The resin (A-IV-1) had an Mw of 7250 and an Mw/Mn ratio of 1.69. The ratio of repeating units derived from the monomers (M-1), (M-6), and (M-12) determined by ¹³C-NMR analysis was 40.2/45.0/14.8 (mol %). The resin had a low-molecular-weight component residual rate of 0.04 mass %.

### Example 25 and Comparative Examples 10 and 11

### Resins (A-IV-2) to (A-IV-4)

Resins (A-IV-2) to (A-IV-4) were synthesized in the same manner as in Example 24, except for changing the composition as shown in Table 14.

The yield (%) of the resins (A-IV-2) to (A-IV-4) is shown in Table 14, and the measurement results for the ratio (mol %) of repeating units determined by ¹³C-NMR analysis, the Mw, the dispersity (Mw/Mn), and the low-molecular-weight component residual rate (mass %) of the resins (A-IV-2) to (A-IV-4) are shown in Table 15.

TABLE 14

| | | Monomer 1 | | Monomer 2 | | Monomer 3 | | | |
|---|---|---|---|---|---|---|---|---|---|
| | | | Amount | | Amount | | Amount | Purification | Yield |
| | Resin | Type | (mol %) | Type | (mol %) | Type | (mol %) | solvent | (%) |
| Example 24 | A-IV-1 | M-1 | 40 | M-6 | 45 | M-12 | 15 | n-Heptane | 76 |
| Example 25 | A-IV-2 | M-1 | 50 | M-3 | 40 | M-4 | 10 | Methanol | 75 |
| Comparative | A-IV-3 | M-8 | 40 | M-6 | 45 | M-12 | 15 | n-Heptane | 76 |
| Example 10 | | | | | | | | | |
| Comparative | A-IV-4 | M-8 | 50 | M-3 | 40 | M-4 | 10 | Methanol | 75 |
| Example 11 | | | | | | | | | |

TABLE 15

| | | | Low- | | | |
|---|---|---|---|---|---|---|
| | | | molecular- | | | |
| | | | weight | | | |
| | | | component | ¹³C-NMR results (mol %)*¹ | | |
| | Mw | Mw/Mn | (mass %) | Monomer 1 | Monomer 2 | Monomer 3 |
| Example 24 | 7250 | 1.69 | 0.04 | 40.2 | 45.0 | 14.8 |
| Example 25 | 7310 | 1.68 | 0.05 | 50.1 | 40.2 | 9.7 |
| Comparative | 7290 | 1.69 | 0.04 | 41.2 | 44.0 | 14.8 |
| Example 10 | | | | | | |
| Comparative | 7380 | 1.62 | 0.05 | 51.1 | 39.0 | 9.9 |
| Example 11 | | | | | | |

*¹Ratio of repeating units derived from monomers

### Example 26

50 parts by mass of the resin (A-IV-1) obtained in Example 24, 50 parts by mass of the resin (A-IV-2) obtained in Example 25, 2.0 parts by mass of 4-cyclohexylphenyldiphenylsulfonium nonafluoro-n-butanesulfonate (B-1) (photoacid generator (B)), 2.0 parts by mass of triphenylsulfonium 1,1,2,2-tetrafluoro-2-(norbornan-2-yl)ethanesulfonate (B-7) (photoacid generator (B)), and 0.23 parts by mass of N-t-butoxycarbonylpyrrolidine (C-3) (nitrogen-containing compound (C)) were mixed. 1400 parts by mass of propylene glycol monomethyl ether acetate (E-1) and 600 parts by mass of ethyl lactate (E-4) (solvent (E)) were added to the mixture to obtain a mixed solution. The mixed solution was filtered through a filter having a pore size of 0.20 μm to prepare a radiation-sensitive resin composition. The composition of the radiation-sensitive resin composition is shown in Table 16.

The sensitivity, the resolution, the cross-sectional pattern shape, the LWR (line width roughness), the minimum pre-collapse dimension, and blob defects of the radiation-sensitive resin composition prepared in Example 26 were evaluated. The evaluation results are shown in Table 17.

### Comparative Example 12

A radiation-sensitive resin composition (Comparative Example 12) was obtained in the same manner as in Example 26, except for changing the components as shown in Table 16. The sensitivity, the resolution, the cross-sectional pattern shape, the LWR (line width roughness), the minimum pre-collapse dimension, and blob defects of the radiation-sensitive resin composition prepared in Comparative Example 12 were evaluated. The evaluation results are shown in Table 17.

TABLE 16

| | | | | | Nitrogen- | | | | | | | |
|---|---|---|---|---|---|---|---|---|---|---|---|---|
| | | | Acid | | containing | | | | | | | |
| | | | generator | | compound | | | | | | | |
| | Resin (A) | | (B) | | (C) | | Solvent (E) | | | | | |
| | | Parts by | | Parts by | | Parts by | | Parts by | PB | | PEB | |
| | Type | mass | Type | mass | Type | mass | Type | mass | Temp. | Time | Temp. | Time |
| Example 26 | A-IV-1 | 50 | B-1 | 2 | C-3 | 0.23 | E-1 | 1400 | 110 | 60 | 115 | 60 |
| | A-IV-2 | 50 | B-7 | 2 | | | E-4 | 600 | | | | |
| Comparative | A-IV-3 | 50 | B-1 | 2 | C-3 | 0.23 | E-1 | 1400 | 110 | 60 | 115 | 60 |
| Example 12 | A-IV-4 | 50 | B-7 | 2 | | | E-4 | 600 | | | | |

TABLE 17

| | | | | | Minimum | |
|---|---|---|---|---|---|---|
| | | | Cross- | | pre- | |
| | | Reso- | sectional | | collapse | |
| | Sensitivity | lution | pattern | LWR | dimension | Blob |
| | (mJ/cm²) | (nm) | shape | (nm) | (nm) | defect |
| Example 26 | 29 | 80 | Good | 6 | 43 | Good |
| Comparative | 30.5 | 90 | Good | 6.9 | 49 | Bad |
| Example 12 | | | | | | |

### Example 27

### Resin (A1-1)

A monomer solution was prepared by dissolving 27.51 g (50 mol %) of the monomer (M-1), 5.29 g (15 mol %) of the monomer (M-3), and 17.20 g (35 mol %) of the monomer (M-6) in 100 g of 2-butanone, and adding 1.72 g (5 mol %) of azobisisobutylonitrile (“AIBN” in Table 18) to the solution.

A 500 ml three-necked flask equipped with a thermometer and a dropping funnel was charged with 50 g of 2-butanone, and purged with nitrogen for 30 minutes. The inside of the flask was then heated to 80° C. with stirring using a magnetic stirrer, and the monomer solution was added dropwise to the flask using the dropping funnel over 3 hours. The monomers were polymerized for 6 hours from the start of the addition of the monomer solution. After completion of polymerization, the polymer solution was cooled with water to 30° C. or less. The reaction mixture was then poured into 1000 g of methanol, and a precipitated white powder was collected by filtration. The white powder was washed twice with 200 g of methanol in a slurry state. The product was then collected by filtration, and dried at 50° C. for 17 hours to obtain a white powdery copolymer (36 g, yield: 72%). This copolymer is referred to as “resin (A1-1)”.

The copolymer had an Mw of 6350 and an Mw/Mn ratio of 1.64. The ratio of repeating units derived from the monomers (M-1), (M-3), and (M-6) determined by ¹³C-NMR analysis was 50.5:14.6:34.9 (mol %). The copolymer had a low-molecular-weight component residual rate of 0.03 mass %. The measurement results are shown in Table 19.

### Examples 28 to 30 and Comparative Examples 13 and 14

### Resins (A1-2) and Resins (A2-1) to (A2-4)

Resins (A1-2) and resins (A2-1) to (A2-4) were synthesized in the same manner as in Example 27, except for changing the composition as shown in Table 18. Note that dimethyl-2,2′-azobisisobutyrate (“MAIB” in Table 18) was used as the initiator in Examples 29 and 30 and Comparative Examples 13 and 14.

The measurement results for the ratio (mol %) of repeating units determined by ¹³C-NMR analysis, the yield (%), the Mw, the dispersity (Mw/Mn), and the low-molecular-weight component residual rate (mass %) of each resin are shown in Table 19.

TABLE 18

| | | Monomer 1 | | Monomer 2 | | Monomer 3 | | Initiator*¹ | |
|---|---|---|---|---|---|---|---|---|---|
| | | | Amount | | Amount | | Amount | | Amount |
| | Resin | Type | (mol %) | Type | (mol %) | Type | (mol %) | Type | (mol %) |
| Example 27 | A1-1 | M-1 | 50 | M-3 | 15 | M-6 | 35 | AIBN | 5 |
| Example 28 | A1-2 | M-1 | 50 | M-2 | 35 | M-7 | 15 | AIBN | 5 |
| Example 29 | A2-1 | M-1 | 20 | M-3 | 50 | M-13 | 30 | MAIB | 8 |
| Example 30 | A2-2 | M-1 | 20 | M-3 | 30 | M-14 | 50 | MAIB | 8 |
| Comparative | A2-3 | M-8 | 20 | M-3 | 50 | M-13 | 30 | MAIB | 8 |
| Example 13 | | | | | | | | | |
| Comparative | A2-4 | M-8 | 20 | M-3 | 30 | M-14 | 50 | MAIB | 8 |
| Example 14 | | | | | | | | | |

*¹Ratio with respect to monomers 1 to 3

TABLE 19

| | | | | | | | | | | | Low-molecular- |
|---|---|---|---|---|---|---|---|---|---|---|---|
| | | ¹³C-NMR results | | | | | | | Molecular | | weight |
| | | Repeating unit 1 | | Repeating unit 2 | | Repeating unit 3 | | | weight | | component |
| | | | Amount | | Amount | | Amount | Yield | | Mw/ | residual rate |
| | Resin | Monomer | (mol %) | Monomer | (mol %) | Monomer | (mol %) | (%) | Mw | Mn | (mass %) |
| Example 27 | A1-1 | M-1 | 50.5 | M-3 | 14.6 | M-6 | 34.9 | 72 | 6350 | 1.64 | 0.03 |
| Example 28 | A1-2 | M-1 | 50.2 | M-2 | 35.1 | M-7 | 14.7 | 73 | 6420 | 1.63 | 0.04 |
| Example 29 | A2-1 | M-1 | 20.4 | M-3 | 50.1 | M-13 | 29.5 | 73 | 4250 | 1.54 | 0.03 |
| Example 30 | A2-2 | M-1 | 20.3 | M-3 | 30.2 | M-14 | 49.5 | 72 | 4390 | 1.56 | 0.06 |
| Comparative | A2-3 | M-8 | 21.2 | M-3 | 48.6 | M-13 | 30.2 | 73 | 4410 | 1.53 | 0.04 |
| Example 13 | | | | | | | | | | | |
| Comparative | A2-4 | M-8 | 21.4 | M-3 | 29.1 | M-14 | 49.5 | 69 | 4620 | 1.51 | 0.04 |
| Example 14 | | | | | | | | | | | |

### Example 31

100 parts by mass of the resin (A1-1) obtained in Example 27, 5.0 parts by mass of the resin (A2-1) obtained in Example 29, 7.0 parts by mass of triphenylsulfonium nonafluoro-n-butanesulfonate (B-1) (photoacid generator (B)), 2.0 parts by mass of 1-(4-n-butoxynaphthalen-1-yl)tetrahydrothiophenium nonafluoro-n-butanesulfonate (B-2) (photoacid generator (B)), and 1.12 parts by mass of N-t-butoxycarbonyl-4-hydroxypiperidine (C-1) (nitrogen-containing compound (D)) were mixed. 1400 parts by mass of propylene glycol monomethyl ether acetate (E-1), 600 parts by mass of cyclohexanone (E-2), and 30 parts by mass of γ-butyrolactone (E-3) (solvent (E)) were added to the mixture to obtain a mixed solution. The mixed solution was filtered through a filter having a pore size of 0.20 μm to prepare a radiation-sensitive resin composition. The composition of the radiation-sensitive resin composition is shown in Table 20.

The sensitivity (1), the resolution (1), the LWR (1), the sensitivity (2), the resolution (2), the LWR (2), and defects due to liquid immersion lithography of the radiation-sensitive resin composition prepared in Example 31 were evaluated. The evaluation results are shown in Table 21.

### Examples 32 to 34 and Comparative Examples 15 to 18

A radiation-sensitive resin composition was obtained in the same manner as in Example 31, except for changing the components as shown in Table 20. The sensitivity (1), the resolution (1), the LWR (1), the sensitivity (2), the resolution (2), the LWR (2), and defects due to liquid immersion lithography of the radiation-sensitive resin compositions prepared in Examples 32 to 34 and Comparative Examples 15 to 18 were evaluated. The evaluation results are shown in Table 21.

TABLE 20

| | | | | | | | Nitrogen- | | | | | | | |
|---|---|---|---|---|---|---|---|---|---|---|---|---|---|---|
| | | | | | Acid | | containing | | | | | | | |
| | First resin | | Second resin | | generator | | compound | | | | | | | |
| | (A1) | | (A2) | | (B) | | (C) | | Solvent (E) | | | | | |
| | | Parts by | | Parts by | | Parts by | | Parts by | | Parts by | PB | | PEB | |
| | Type | mass | Type | mass | Type | mass | Type | mass | Type | mass | Temp. | Time | Temp. | Time |
| Example 31 | A1-1 | 100 | A2-1 | 5.0 | B-1 | 7.0 | C-1 | 1.12 | E-1 | 1400 | 110 | 60 | 115 | 60 |
| | | | | | B-2 | 2.0 | | | E-2 | 600 | | | | |
| | | | | | | | | | E-3 | 30 | | | | |
| Example 32 | A1-2 | 100 | A2-1 | 5.0 | B-1 | 7.0 | C-1 | 1.53 | E-1 | 1400 | 110 | 60 | 100 | 60 |
| | | | | | B-2 | 2.0 | | | E-2 | 600 | | | | |
| | | | | | | | | | E-3 | 30 | | | | |
| Example 33 | A1-1 | 100 | A2-2 | 5.0 | B-1 | 7.0 | C-1 | 1.12 | E-1 | 1400 | 110 | 60 | 115 | 60 |
| | | | | | B-2 | 2.0 | | | E-2 | 600 | | | | |
| | | | | | | | | | E-3 | 30 | | | | |
| Example 34 | A1-2 | 100 | A2-2 | 5.0 | B-1 | 7.0 | C-1 | 1.53 | E-1 | 1400 | 110 | 60 | 100 | 60 |
| | | | | | B-2 | 2.0 | | | E-2 | 600 | | | | |
| | | | | | | | | | E-3 | 30 | | | | |
| Comparative | A1-1 | 100 | A2-3 | 5.0 | B-1 | 7.0 | C-1 | 1.12 | E-1 | 1400 | 110 | 60 | 115 | 60 |
| Example 15 | | | | | B-2 | 2.0 | | | E-2 | 600 | | | | |
| | | | | | | | | | E-3 | 30 | | | | |
| Comparative | A1-2 | 100 | A2-3 | 5 0 | B-1 | 7.0 | C-1 | 1.53 | E-1 | 1400 | 110 | 60 | 100 | 60 |
| Example 16 | | | | | B-2 | 2.0 | | | E-2 | 600 | | | | |
| | | | | | | | | | E-3 | 30 | | | | |
| Comparative | A1-1 | 100 | A2-4 | 5.0 | B-1 | 7.0 | C-1 | 1.12 | E-1 | 1400 | 110 | 60 | 115 | 60 |
| Example 17 | | | | | B-2 | 2.0 | | | E-2 | 600 | | | | |
| | | | | | | | | | E-3 | 30 | | | | |
| Comparative | A1-2 | 100 | A2-4 | 5.0 | B-1 | 7.0 | C-1 | 1.53 | E-1 | 1400 | 110 | 60 | 100 | 60 |
| Example 18 | | | | | B-2 | 2.0 | | | E-2 | 600 | | | | |
| | | | | | | | | | E-3 | 30 | | | | |

TABLE 21

| | | | | | | | Defect due |
|---|---|---|---|---|---|---|---|
| | Sensitivity | Resolution | | Sensitivity | Resolution | | to liquid |
| | (1) | (1) | LWR (1) | (2) | (2) | LWR (2) | immersion |
| | (mJ/cm²) | (nm) | (nm) | (mJ/cm²) | (nm) | (nm) | lithography |
| Example 31 | 33.5 | 80 | 5.8 | 16.0 | 42 | 5.6 | Good |
| Example 32 | 36.5 | 85 | 5.6 | 17.5 | 42 | 4.3 | Good |
| Example 33 | 33.0 | 85 | 5.7 | 16.5 | 44 | 5.7 | Good |
| Example 34 | 36.0 | 60 | 5.6 | 17.0 | 42 | 4.4 | Good |
| Comparative | 34.0 | 85 | 7.3 | 16.5 | 46 | 5.8 | Bad |
| Example 15 | | | | | | | |
| Comparative | 37.0 | 85 | 6.1 | 18.0 | 46 | 4.8 | Bad |
| Example 16 | | | | | | | |
| Comparative | 33.5 | 85 | 7.2 | 17.0 | 46 | 6.2 | Bad |
| Example 17 | | | | | | | |
| Comparative | 36.5 | 85 | 6.2 | 17.5 | 46 | 4.9 | Bad |
| Example 18 | | | | | | | |

As is clear from the above results, the radiation-sensitive resin compositions according to the examples of the invention exhibited excellent sensitivity and excellent resolution. The radiation-sensitive resin compositions according to the examples of the invention also exhibited improved dry etching resistance (minimum pre-collapse dimension) LWR, PEB temperature dependence, and the like. The radiation-sensitive resin compositions according to the examples of the invention also showed excellent results for the cross-sectional pattern shape and blob defects.

According to the embodiment of the present invention, the radiation-sensitive resin composition utilizes a polymer that includes the repeating unit (A1) shown by the formula (1) and the acid-dissociable group-containing repeating unit as the resin component. In particular, a polymer that includes at least two repeating units having a specific chemical structure as the resin component. As a result, the above radiation-sensitive resin composition may suitably used as a chemically-amplified resist that exhibits excellent resolution, small LWR, small PEB temperature dependence, excellent pattern collapse resistance, and excellent defect resistance. The above radiation-sensitive resin composition may suitably be used for lithography that utilizes an ArF excimer laser as a light source, and exhibits excellent performance as a chemically-amplified resist during liquid immersion lithography or when forming a fine pattern having a line width of 90 nm or less.

The radiation-sensitive resin composition according to the embodiment of the invention may be used for lithography (particularly lithography that utilizes an ArF excimer laser as a light source) for forming a fine pattern having a line width of 90 nm of less. The radiation-sensitive resin composition may also be used for liquid immersion lithography as a chemically-amplified resist that exhibits excellent resolution, small LWR, excellent PEB temperature dependence, excellent pattern collapse resistance, and excellent defect resistance.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition comprising:
a resin including a polymer comprising:
a first repeating unit shown by a following formula (1); and
an acid-dissociable group-containing repeating unit; and
a photoacid generator, 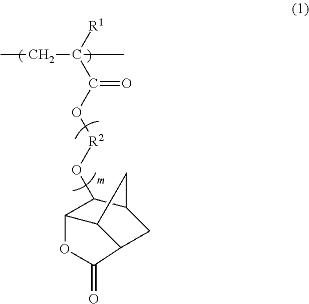
wherein R¹ represents a hydrogen atom or a methyl group, R² represents an alkylene group having 1 to 12 carbon atoms or an alicyclic alkylene group, and m is an integer from 1 to 3.

2. The radiation-sensitive resin composition according to claim 1, wherein the acid-dissociable group-containing repeating unit includes a second repeating unit shown by a following formula (2), 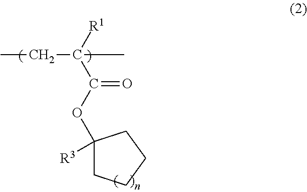
wherein R¹ represents a hydrogen atom or a methyl group, R³ represents an alkyl group having 1 to 4 carbon atoms, and n is an integer from 1 to 5.

3. The radiation-sensitive resin composition according to claim 1, wherein the acid-dissociable group-containing repeating unit includes at least one of a third repeating unit shown by a following formula (3-1) and a fourth repeating unit shown by a following formula (3-2), 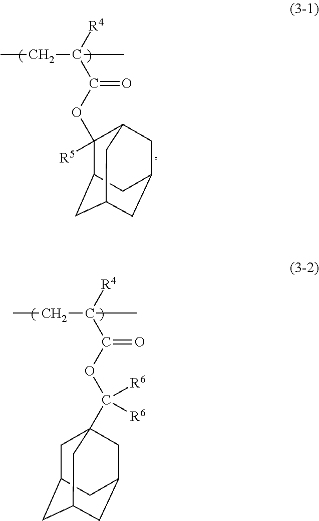
wherein R⁴ represents a hydrogen atom, a methyl group, or a trifluoromethyl group, R⁵ represents an alkyl group having 1 to 4 carbon atoms, and each R⁶ represents an alkyl group having 1 to 4 carbon atoms.

4. The radiation-sensitive resin composition according to claim 1, wherein the polymer includes a fifth repeating unit shown by a following formula (4), 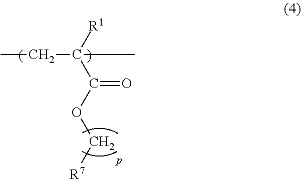
wherein R¹ represents a hydrogen atom or a methyl group, R⁷ represents a hydrogen atom, a hydroxyl group, or an acyl group, and p is an integer from 1 to 18.

5. The radiation-sensitive resin composition according to claim 1, wherein the polymer includes a fluorine-containing repeating unit shown by a following formula (5-1) or (5-2), 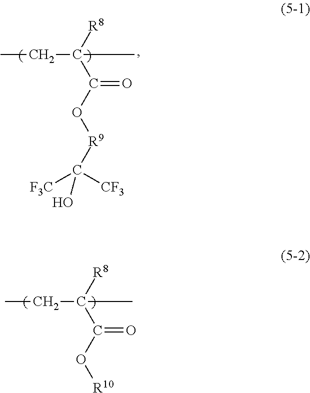
wherein R⁸ represents a hydrogen atom, an alkyl group having 1 to 4 carbon atoms, a trifluoromethyl group, or a hydroxymethyl group, R⁹ represents a divalent chain or cyclic hydrocarbon group, and R¹⁰ represents linear, branched, or cyclic fluoroalkyl group having 1 to 12 carbon atoms in which at least one hydrogen is substituted with a fluorine atom.

6. The radiation-sensitive resin composition according to claim 1, wherein the polymer includes a sixth repeating unit shown by a following formula (6), 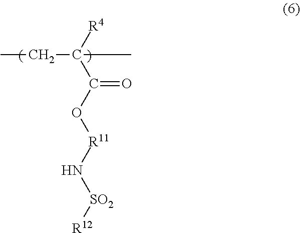
wherein R⁴ represents a hydrogen atom, a methyl group, or a trifluoromethyl group, R¹¹ represents a single bond, a methylene group, a linear or branched alkylene group having 2 to 20 carbon atoms, or a divalent cyclic hydrocarbon group, and R¹² represents a linear or branched alkyl group having 1 to 10 carbon atoms that includes at least one fluorine atom, or an alicyclic alkyl group having 3 to 10 carbon atoms.

7. The radiation-sensitive resin composition according to claim 1, wherein the resin includes 100 parts by mass of a first resin, and about 0.1 to about 20 parts by mass of a second resin, the first resin comprising a polymer that becomes alkali-soluble due to an acid and that does not include a fluorine atom, and the second resin comprising a polymer that includes the first repeating unit and a fluorine-containing repeating unit shown by a following formula (5-1) or (5-2), 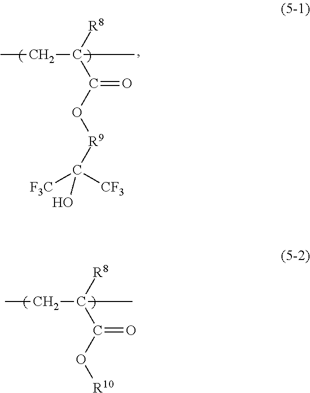
wherein R⁸ represents a hydrogen atom, an alkyl group having 1 to 4 carbon atoms, a trifluoromethyl group, or a hydroxymethyl group, R⁹ represents a divalent chain or cyclic hydrocarbon group, and R¹⁰ represents linear, branched, or cyclic fluoroalkyl group having 1 to 12 carbon atoms in which at least one hydrogen is substituted with a fluorine atom.

8. The radiation-sensitive resin composition according to claim 1, wherein the photoacid generator includes a photoacid generator that includes a compound shown by a following formula (9), 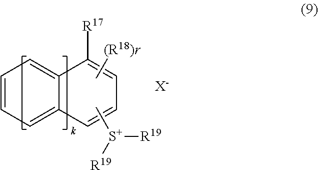
wherein R¹⁷ represents a hydrogen atom, a fluorine atom, a hydroxyl group, a linear or branched alkyl group having 1 to 10 carbon atoms, a linear or branched alkoxy group having 1 to 10 carbon atoms, or a linear or branched alkoxycarbonyl group having 2 to 11 carbon atoms, R¹⁸ represents a linear or branched alkyl group having 1 to 10 carbon atoms, an alkoxy group having 1 to 10 carbon atoms, or a linear, branched, or cyclic alkanesulfonyl group having 1 to 10 carbon atoms, r is an integer from 0 to 10, R¹⁹ represents a linear or branched alkyl group having 1 to 10 carbon atoms, a substituted or unsubstituted phenyl group, a substituted or unsubstituted naphthyl group, or a substituted or unsubstituted divalent group having 2 to 10 carbon atoms formed by R¹⁹ and R¹⁹ bonding to each other, k is an integer from 0 to 2, X⁻ represents an anion shown by a following formula (10-1), (10-2), (10-3), or (10-4), 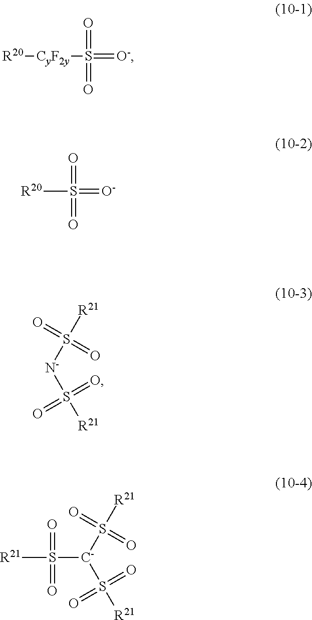
R²⁰ represents a hydrogen atom, a fluorine atom, or a substituted or unsubstituted hydrocarbon group having 1 to 12 carbon atoms, y is an integer from 1 to 10, R²¹ represents a linear or branched fluoroalkyl group having 1 to 10 carbon atoms, or a substituted or unsubstituted divalent fluorine-containing group having 2 to 10 carbon atoms formed by R²¹ and R²¹ bonding to each other.

9. A polymer having a weight average molecular weight of 1000 to 100,000 and comprising:
a first repeating unit shown by a following formula (1); and
an acid-dissociable group-containing repeating unit, 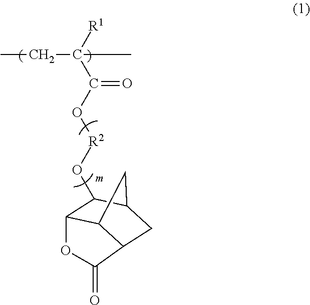
wherein R¹ represents a hydrogen atom or a methyl group, R² represents an alkylene group having 1 to 12 carbon atoms or an alicyclic alkylene group, and m is an integer from 1 to 3.

10. The polymer according to claim 9, wherein the acid-dissociable group-containing repeating unit comprises a second repeating unit shown by a following formula (2), 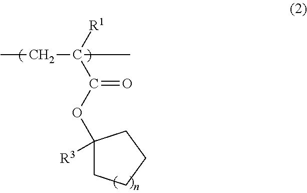
wherein R¹ represents a hydrogen atom or a methyl group, R³ represents an alkyl group having 1 to 4 carbon atoms, and n is an integer from 1 to 5.

11. The polymer according to claim 9, wherein the acid-dissociable group-containing repeating unit includes at least one of a third repeating unit shown by a following formula (3-1) and a fourth repeating unit shown by a following formula (3-2), 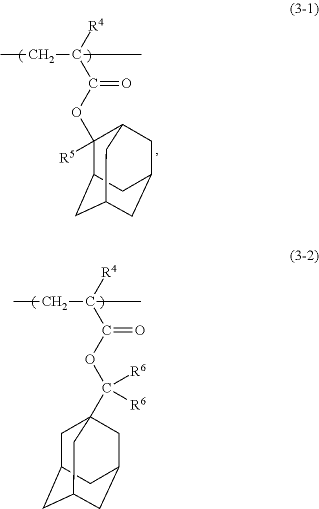
wherein R⁴ represents a hydrogen atom, a methyl group, or a trifluoromethyl group, R⁵ represents an alkyl group having 1 to 4 carbon atoms, and each R⁶ represents an alkyl group having 1 to 4 carbon atoms.

12. The polymer according to claim 9, further comprising:
a fifth repeating unit shown by a following formula (4), 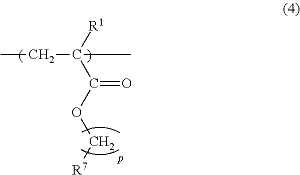
wherein R¹ represents a hydrogen atom or a methyl group, R⁷ represents a hydrogen atom, a hydroxyl group, or an acyl group, and p is an integer from 1 to 18.

13. The polymer according to claim 9, further comprising:
a fluorine-containing repeating unit shown by a following formula (5-1) or (5-2), 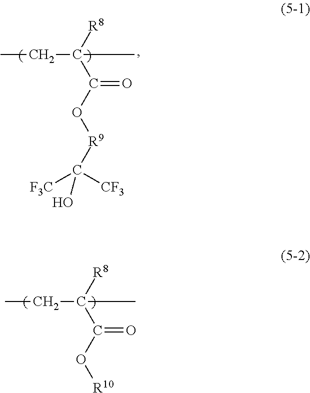
wherein R⁸ represents a hydrogen atom, an alkyl group having 1 to 4 carbon atoms, a trifluoromethyl group, or a hydroxymethyl group, R⁹ represents a divalent chain or cyclic hydrocarbon group, and R¹⁰ represents linear, branched, or cyclic fluoroalkyl group having 1 to 12 carbon atoms in which at least one hydrogen is substituted with a fluorine atom.

14. The polymer according to claim 9, further comprising:
a sixth repeating unit shown by a following formula (6), 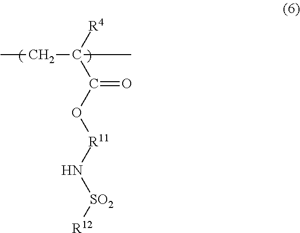
wherein R⁴ represents a hydrogen atom, a methyl group, or a trifluoromethyl group, R¹¹ represents a single bond, a methylene group, a linear or branched alkylene group having 2 to 20 carbon atoms, or a divalent cyclic hydrocarbon group, and R¹² represents a linear or branched alkyl group having 1 to 10 carbon atoms that includes at least one fluorine atom, or an alicyclic alkyl group having 3 to 10 carbon atoms.

15. The radiation-sensitive resin composition according to claim 2, wherein the acid-dissociable group-containing repeating unit includes at least one of a third repeating unit shown by a following formula (3-1) and a fourth repeating unit shown by a following formula (3-2), 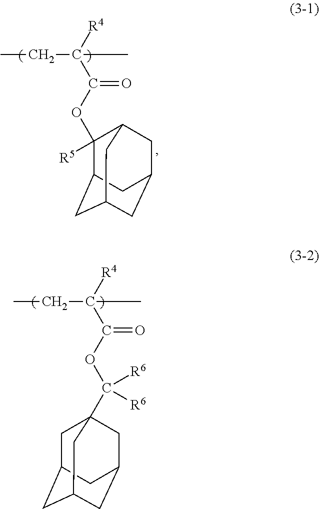
wherein R⁴ represents a hydrogen atom, a methyl group, or a trifluoromethyl group, R⁵ represents an alkyl group having 1 to 4 carbon atoms, and each R⁶ represents an alkyl group having 1 to 4 carbon atoms.

16. The radiation-sensitive resin composition according to claim 2, wherein the polymer includes a fifth repeating unit shown by a following formula (4), 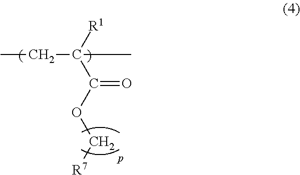
wherein R¹ represents a hydrogen atom or a methyl group, R⁷ represents a hydrogen atom, a hydroxyl group, or an acyl group, and p is an integer from 1 to 18.

17. The radiation-sensitive resin composition according to claim 2, wherein the polymer includes a fluorine-containing repeating unit shown by a following formula (5-1) or (5-2), 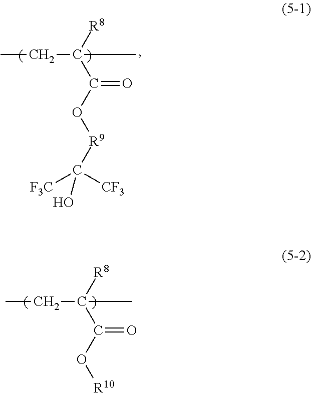
wherein R⁸ represents a hydrogen atom, an alkyl group having 1 to 4 carbon atoms, a trifluoromethyl group, or a hydroxymethyl group, R⁹ represents a divalent chain or cyclic hydrocarbon group, and R¹⁰ represents linear, branched, or cyclic fluoroalkyl group having 1 to 12 carbon atoms in which at least one hydrogen is substituted with a fluorine atom.

18. The radiation-sensitive resin composition according to claim 2, wherein the polymer includes a sixth repeating unit shown by a following formula (6), 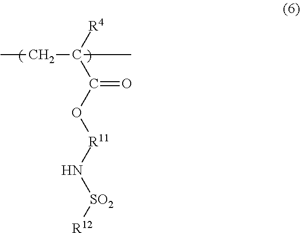
wherein R⁴ represents a hydrogen atom, a methyl group, or a trifluoromethyl group, R¹¹ represents a single bond, a methylene group, a linear or branched alkylene group having 2 to 20 carbon atoms, or a divalent cyclic hydrocarbon group, and R¹² represents a linear or branched alkyl group having 1 to 10 carbon atoms that includes at least one fluorine atom, or an alicyclic alkyl group having 3 to 10 carbon atoms.
